(19) United States
(12) Patent Application Publication
(10) Pub. No.: US 2005/0170641 A1
(43) Pub. Date: Aug. 4, 2005

(54) Multilayered wiring structure, method of forming buried wiring, semiconductor device, method of manufacturing semiconductor device, semiconductor mounted device, and method of manufacturing semiconductor mounted device

(75) Inventors: Seiichi Kondo, Ibaraki (JP); Kaori Misawa, Gifu (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 11/014,883

(22) Filed: Dec. 20, 2004

(30) Foreign Application Priority Data
Jan. 30, 2004 (JP) 2004-024539
Jan. 30, 2004 (JP) 2004-024540

(51) Int. Cl. H01L 21/4763; H01L 21/44

(52) U.S. Cl. 438/633; 438/634; 438/640

(57) ABSTRACT

A method of forming a buried wiring in a low-k dielectric film, includes: forming a low-k dielectric film having a dielectric constant of 3 or less on an underlayer; removing the low-k dielectric film by a first width from an edge of the underlayer; forming a cap film on the low-k dielectric film, after removing the low-k dielectric film by the first width; forming a groove in the cap film and the low-k dielectric film; forming a conductive film in the groove and on the cap film; removing the conductive film by a second width, different from the first width by 1 mm or more, from the edge of the underlayer; and polishing unnecessary portions of the conductive film on the cap film, after removing the conductive film by the second width.

### FIELD OF THE INVENTION

The present invention relates to a multilayered wiring structure, a method of forming buried wiring, a semiconductor device, a method of manufacturing a semiconductor device, a semiconductor mounted device, and a method of manufacturing a semiconductor mounted device. Particularly the present invention relates to the forming of a buried wiring structure in which a low-k dielectric film is combined with a Cu wiring.

### DESCRIPTION OF THE BACKGROUND ART

With high integration and high performance of a semiconductor integrated circuit (hereinafter referred to as the “LSI”), new fine processing techniques have been proposed. As one of the techniques, a chemical mechanical polishing (hereinafter referred to as “CMP”) method has been proposed, and the CMP method is utilized especially in planarization of an interlayer insulating film forming a metal plug, and forming a buried wiring in a multilevel wiring forming step (see, e.g., U.S. Pat. No. 4,944,836).

In recent years, a signal delay of a wiring has raised a problem, and movement to change a wiring material to a low-resistance Cu alloy from a conventional Al alloy has been pushed forward. It is difficult to perform finely processing the Cu alloy by dry etching, and therefore a so-called damascene method has been adopted in which a groove is formed in an insulating film, a Cu film is deposited in the groove, and unnecessary portions of the Cu film except in the groove is removed using the CMP method to thereby form a buried Cu wiring (see, e.g., Japanese Patent Application Laid-Open No. H2-278822).

Furthermore, an LSI has been developed using a low-k dielectric film having a dielectric constant lower than that of a SiO₂ film as an interlayer insulating film in order to reduce a parasitic capacity between wirings. That is, a low-k dielectric film having a dielectric constant k of 1.5 to 3.5 is used instead of the SiO₂ film having a dielectric constant k of about 4.2. Development of a low-k dielectric film material having k of 2.5 or less has also been pushed forward. The material having k of 2.5 or less is a porous low-k dielectric film material in which pores are introduced in many cases.

However, the low-k dielectric film has a low mechanical strength as compared with the SiO₂ film. Therefore, to form a multilayered wiring structure in which the low-k dielectric film is combined with the Cu wiring, there have been problems that cohesive delamination occurs in a low-k dielectric film by a polishing pressure in the CMP, and a cap film or a lower insulating film contacting the low-k dielectric film peels. Especially, when a low-k dielectric film material having a low Young's modulus or hardness, or a low-k dielectric film material having low adhesion to the cap film is used, the above-described problems are remarkably caused. A result has been reported that the peeling easily occurs, especially when the Young's modulus of the low-k dielectric film is 5 GPa or less (see, e.g., “Low-k Dielectrics Characterization for Damascene Integration”, 2001, IITC 2001 by Simon Lin and other eleven people).

When the low-k dielectric film peels during Cu-CMP, a wafer edge is a starting point in many cases (see, e.g., “Copper CMP at Low Shear Force for Low-k Compatability”, 2002, IITC 2002 by Stan Tsai and other six people). Moreover, as a polishing time lengthens, there is a tendency that a peeling area increases toward a central direction of a wafer.

To solve the problem, the peeling of the low-k dielectric film has heretofore been reduced, when the polishing pressure of the CMP is lowered. On the other hand, the use of the low-k dielectric film material having a high Young's modulus or hardness is effective for preventing the peeling of the low-k dielectric film.

However, when the polishing pressure of the CMP is lowered, there has been a problem that polishing rate drops, and throughput decreases. When the Young's modulus or hardness is raised, there has been a problem the dielectric constant k increases.

The peeling of the low-k dielectric film during the Cu-CMP raises a large problem in the development of the Cu wiring. Even when the peeling area is reduced, the peeling of the low-k dielectric film at the wafer edge is hardly solved.

### SUMMARY OF THE INVENTION

The present invention has been conceived to solve the previously-mentioned problems and a general object of the present invention is to provide novel and useful multilayered wiring structure, method of forming buried wiring, semiconductor device, method of manufacturing a semiconductor device, semiconductor mounted device, and method of manufacturing a semiconductor mounted device.

More specific object of the present invention is to prevent a low-k dielectric film from being peeled in polishing a conductive film. The above object of the present invention is attained by a following semiconductor device and a following method for manufacturing a semiconductor device.

According to first aspect of the present invention, the method of forming a buried wiring in a low-k dielectric film, comprises: forming a low-k dielectric film having a dielectric constant of 3 or less on an underlayer; removing the low-k dielectric film by a first width from an edge of the underlayer; forming a cap film on the low-k dielectric film, after removing the low-k dielectric film by the first width; forming a groove in the cap film and the low-k dielectric film; forming a conductive film in the groove and on the cap film; removing the conductive film by a second width different from the first width by 1 mm or more from the edge of the underlayer; and polishing unnecessary portions of the conductive film formed on the cap film, after removing the conductive film by the second width.

According to second aspect of the present invention, the method of manufacturing a semiconductor device, comprises: forming a semiconductor element having a diffusion layer on a substrate; forming an interlayer insulating film covering the semiconductor element; forming a contact connected to the diffusion layer in the interlayer insulating film; forming a low-k dielectric film having a dielectric constant of 3 or less on the contact and the interlayer insulating film; removing the low-k dielectric film by a first width from an edge of the substrate; forming a cap film on the low-k dielectric film, after removing the low-k dielectric film by the first width; forming a groove reaching a top surface of the contact in the cap film and the low-k dielectric film; forming a conductive film in the groove and on the cap film; removing the conductive film by a second width different from the first width by 1 mm or more from the edge of the substrate; and polishing unnecessary portions of the conductive film formed on the cap film, after removing the conductive film.

According to third aspect of the present invention, the method of manufacturing a semiconductor mounted device, comprises: forming a low-k dielectric film having a dielectric constant of 3 or less on a semiconductor device having a semiconductor element; removing the low-k dielectric film by a first width from an edge of the semiconductor device; forming a cap film on the low-k dielectric film, after removing the low-k dielectric film by the first width; forming a groove in the cap film and the low-k dielectric film; forming a conductive film in the groove and on the cap film; removing the conductive film by a second width different from the first width by 1 mm or more from the edge of the semiconductor device; and polishing unnecessary portions of the unnecessary conductive film formed on the cap film, after removing the conductive film by the second width.

According to fourth aspect of the present invention, the multilayered wiring structure comprises: a first low-k dielectric film formed on a substrate and removed by a first width from an edge of the substrate; a first conductive layer buried in a first opening formed in the first low-k dielectric film; a second low-k dielectric film formed on the first conductive film and the first low-k dielectric film, and removed by a second width smaller than the first width by 0.7 mm or more from the edge of the substrate; and a second conductive layer buried in a second opening formed in the second low-k dielectric film.

According to fifth aspect of the present invention, the multilayered wiring structure comprises: a first low-k dielectric film formed on a substrate and removed by a first width from an edge of the substrate; a first conductive layer buried in a first opening formed in the first low-k dielectric film; a second low-k dielectric film formed on the first conductive film and the first low-k dielectric film and removed by a second width larger than the first width by 0.4 mm or more from the edge of the substrate; and a second conductive layer buried in a second opening formed in the second low-k dielectric film.

According to sixth aspect of the present invention, the semiconductor device comprises: a semiconductor element formed on a substrate and having a diffusion layer; an interlayer insulating film covering the semiconductor element; a contact formed in the interlayer insulating film and connected to the diffusion layer; a first low-k dielectric film formed on the contact and the interlayer insulating film, and removed by a first width from an edge of the substrate; a first conductive layer buried in a first opening formed in the first low-k dielectric film; a second low-k dielectric film formed on the first conductive layer and the first low-k dielectric film, and removed by a second width smaller than the first width by 0.7 mm or more from the edge of the substrate; and a second conductive layer buried in a second opening formed in the second low-k dielectric film.

According to seventh aspect of the present invention, the semiconductor device comprises: a semiconductor element formed on a substrate and having a diffusion layer; an interlayer insulating film covering the semiconductor element; a contact formed in the interlayer insulating film and connected to the diffusion layer; a first low-k dielectric film formed on the contact and the interlayer insulating film, and removed by a first width from an edge of the substrate; a first conductive layer buried in a first opening formed in the first low-k dielectric film; a second low-k dielectric film formed on the first conductive layer and the first low-k dielectric film, and removed by a second width larger than the first width by 0.4 mm or more from the edge of the substrate; and a second conductive layer buried in a second opening formed in the second low-k dielectric film.

According to eighth aspect of the present invention, the semiconductor mounted device comprises: a semiconductor chip having a semiconductor element and an upper wiring on a substrate; a first low-k dielectric film formed on the semiconductor chip and removed by a first width from an edge of the semiconductor chip; a first conductive layer buried in a first opening formed in the first low-k dielectric film; a second low-k dielectric film formed on the first conductive film and the first low-k dielectric film, and removed by a second width smaller than the first width by 0.7 mm or more from the edge of the substrate; and a second conductive layer buried in a second opening formed in the second low-k dielectric film.

According to ninth aspect of the present invention, the semiconductor mounted device comprises: a semiconductor chip having a semiconductor element and an upper wiring on a substrate; a first low-k dielectric film formed on the semiconductor chip and removed by a first width from an edge of the semiconductor chip; a first conductive layer buried in a first opening formed in the first low-k dielectric film; a second low-k dielectric film formed on the first conductive film and the first low-k dielectric film, and removed by a second width larger than the first width by 0.4 mm or more from the edge of the substrate; and a second conductive layer buried in a second opening formed in the second low-k dielectric film.

Other objects and further features of the present invention will be apparent from the following detailed description when read in conjunction with the accompanying drawings.

### BRIEF DESCRIPTION OF THE DRAWINGS

FIGS. 1A to 1D are process sectional views showing a method for forming a wiring according to First Embodiment of the present invention;

FIG. 2 is a process sectional view showing the case that the low-k dielectric film formed on outer peripheral portion of the substrate is removed by dry etching;

FIG. 3 is a diagram showing a relationship between the film thickness of the Cu film and an edge removed width difference necessary for preventing the low-k dielectric film from being peeled;

FIGS. 4A to 4D are process sectional views showing a method for forming a wiring according to Second Embodiment of the present invention;

FIGS. 5A to 5D are process sectional views showing a method of manufacturing a semiconductor device according to Third Embodiment of the present invention;

FIG. 6 is a process sectional view showing a method of manufacturing a liquid crystal display device according to Fourth Embodiment of the present invention;

FIGS. 7A to 7D are process sectional views showing a method of manufacturing a semiconductor device according to Fifth Embodiment of the present invention;

FIGS. 8A and 8B are process sectional. views showing a method of manufacturing a semiconductor mounted device according to Sixth Embodiment of the present invention;

FIGS. 9A and 9B are process sectional views showing a method of manufacturing a semiconductor mounted device according to Seventh Embodiment of the present invention;

FIG. 10 is a sectional view showing the semiconductor mounted device according to Eighth Embodiment;

FIG. 11 is a sectional view showing a multilayered wiring structure according to Ninth Embodiment of the present invention;

FIG. 12 is a diagram showing a relationship between the film thickness of the low-k dielectric film and an edge removed width difference necessary for preventing the low-k dielectric film from being peeled;

FIGS. 13A to 13D are process sectional views showing a method of forming a multilayered wiring according to Ninth Embodiment;

FIG. 14 is a sectional view showing a comparative example of Ninth Embodiment;

FIG. 15 is a sectional view showing a multilayered wiring structure according to Tenth Embodiment;

FIGS. 16A to 16D are process sectional view showing a method of forming a wiring according to Tenth Embodiment;

FIGS. 17A to 17E are process sectional views showing a method of forming a wiring according to Eleventh Embodiment of the present invention;

FIG. 18 is a sectional view showing a semiconductor device according to Twelfth Embodiment of the present invention;

FIGS. 19A to 19C are process sectional views showing a method of manufacturing a semiconductor device according to Twelfth Embodiment of the present invention;

FIG. 20 is a sectional view showing a semiconductor device according to Thirteenth Embodiment;

FIGS. 21A to 21C are process sectional views showing a method of manufacturing a semiconductor device according to Thirteenth Embodiment;

FIG. 22 is a sectional view showing a semiconductor mounted device according to Fourteenth Embodiment;

FIGS. 23A to 23C are process sectional views showing a method of manufacturing a semiconductor mounted device according to Fourteenth Embodiment;

FIG. 24 is a sectional view showing a semiconductor mounted device according to Fifteenth Embodiment;

FIGS. 25A to 25C are process sectional views showing a method of manufacturing a semiconductor mounted device according to Fifteenth Embodiment; and

FIG. 26 is a sectional view showing a semiconductor mounted device according to Sixteenth Embodiment.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

The present inventor first inspected a correct starting point of peeling of a low-k dielectric film in Cu-CMP. According to this inspection, the peeling starting point of the low-k dielectric film is a wafer outer peripheral portion on which the low-k dielectric film is formed, that is, an edge portion of the low-k dielectric film. In detail, since the low-k dielectric film is removed by a width of about 2 mm from a wafer edge immediately after spin-coating the low-k dielectric film, an actual peeling starting point is at 2 mm inside the wafer edge. Reasons why the low-k dielectric film is removed at the wafer edge in this manner are two purposes: one purpose of removing coating unevenness of the low-k dielectric film generated around a wafer notch or orientation flat; and another purpose of preventing particles from being generated by the low-k dielectric film formed on the wafer edge, which contacts a wafer case or a wafer carrier and peels. Therefore, the low-k dielectric film on the wafer edge needs to be removed, but the corresponding portion is the starting point of the peeling of the low-k dielectric film in the Cu-CMP.

Not only the low-k dielectric film but also a Cu film formed by an electrolytic plating method are removed from the wafer edge by a width of about 2 mm. The reason is that as to the Cu film formed on the wafer edge, the Cu film sticks to the wafer case or the wafer carrier, and moves to another wafer during the process, and finally a problem of metal contamination is caused. The Cu film formed by the electrolytic plating method is not formed outside a plated electrode, but a seed Cu film formed by a sputtering method is formed to a wafer outermost periphery. Therefore, a film thickness of the plated Cu film becomes non-uniform about 1 mm inside the plated electrode. The corresponding portion is removed after the plating, and accordingly a portion which remains non-polished is prevented from being generated in a Cu-CMP process.

Therefore, both the low-k dielectric film and the Cu film are removed at a distance of about 2 mm from the wafer edge, and the low-k dielectric film peels from the portion at about 2 mm inside the wafer edge in the Cu-CMP.

A strong stress is applied to the edge portion of the wafer during the Cu-CMP. For example, even when a polishing pressure is set to 3 psi, and the Cu-CMP is performed, a pressure of 3.5 psi to 7 psi is applied to a region of about 2 mm from the wafer edge. This is because the wafer edge portion is strongly pressed against a polishing pad. When there is an edge of the low-k dielectric film in the region of about 2 mm from this wafer edge, the low-k dielectric film is polished with a substantially high polishing pressure, and the low-k dielectric film easily peels. Since there is a step portion corresponding to the film thickness of the low-k dielectric film in the edge of the low-k dielectric film, the polishing pressure is concentrated. Once the peeling of the low-k dielectric film starts., a peeling area increases with a polishing time, and finally the film peels to a wafer central portion.

On the other hand, a strong stress is also applied to the Cu film during the CMP. Especially, the stress of the CMP is concentrated on the Cu film edge in the region of about 2 mm from the wafer edge. When the low-k dielectric film edge exists in the same position as that of the Cu film edge, the low-k dielectric film easily peels. Since the step portion corresponding to the film thickness of the Cu film is generated on the edge of the Cu film, the CMP pressure is concentrated. Furthermore, when the edge of the low-k dielectric film exists there, a step portion corresponding to a total film thickness of the low-k dielectric film and the Cu film exists on the wafer edge, and the stress of the CMP is excessively concentrated on the step portion. That is, the wafer outermost peripheral portion is polished with a substantially high polishing pressure, and the low-k dielectric film easily peels. Once the peeling of the low-k dielectric film starts, the peeling area increases with the polishing time, and finally the film entirely peels to the wafer central portion.

Furthermore, since the low-k dielectric film is formed as the interlayer insulating film in each wiring layer and via-layer, at least six layers of low-k dielectric films are formed, and the number of the layers exceeds ten at least, when forming the multilayered wiring. Additionally, since the film thickness of the low-k dielectric film increases toward the wiring layer in the upper, the step portion of the low-k dielectric film in the substrate edge becomes high toward the wiring layer of the upper. Therefore, the problem of the peeling of the lower low-k dielectric film becomes more serious in the Cu-CMP when forming the upper wiring.

In the present invention, the wafer edge removed width of the low-k dielectric film after applying the low-k dielectric film is set to be distant from that of the Cu film after depositing the Cu film by electrolytic plating. Accordingly the low-k dielectric film is prevented from being peeled in the-Cu-CMP.

First Embodiment

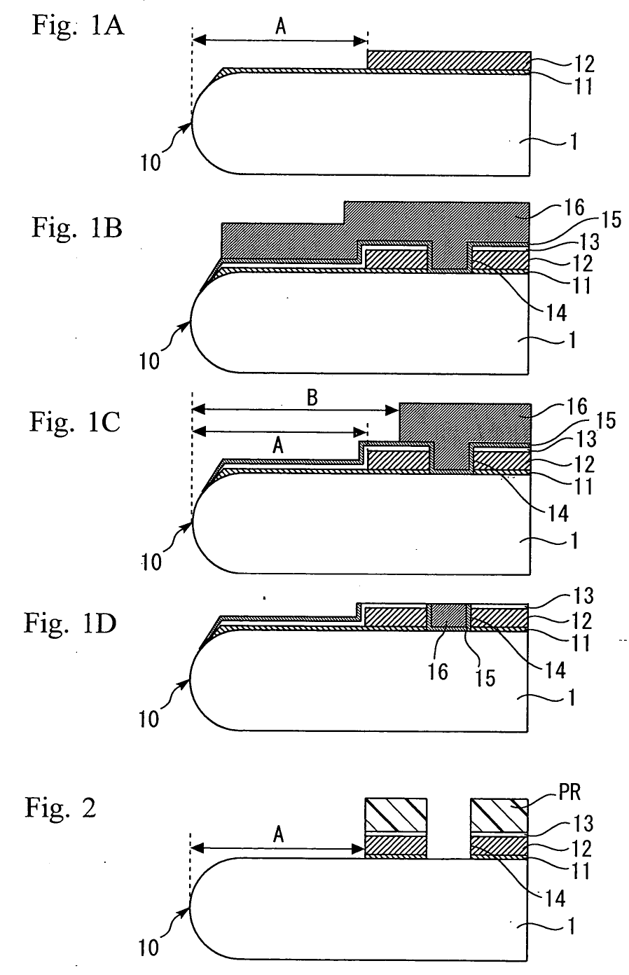

FIGS. 1A to 1D are process sectional views showing a method for forming a wiring according to First Embodiment of the present invention.

As shown in FIG. 1A, a diffusion barrier film 11 is formed, for example, in a film thickness of 30 nm to 200 nm on a substrate 1 serving as an underlayer (also called “a base”) by a CVD method. As the substrate 1, for example, a printed board, a semiconductor chip or the like is usable besides a substrate such as a silicon substrate. As the diffusion barrier film 11, for example, a SiO₂ film, a SiC film, a SiCN film, a SiCO film, or a SiN film is usable.

Next, immediately after a low-k dielectric film 12 is formed, for example, in a film thickness of 100 nm to 1000 nm on the diffusion barrier film 11 by a spin coating method, the low-k dielectric film 12 of a substrate outer peripheral portion is removed by a width A by a chemical solution. The removed width A, that is, the length from a substrate edge 10 to the edge of the low-k dielectric film 12 is preferably 4 mm or more and 15 mm or less. After removing the low-k dielectric film 12, baking and curing are performed in an inactive gas atmosphere, and further the surface of the low-k dielectric film 12 is reformed by irradiation with He plasma. As the low-k dielectric film 12, for example, a methyl silsesquioxane (MSQ) film, a hydrogen silsesquioxane (HSQ) film, a polymer (e.g., SiLK (registered trademark manufactured by Dow Chemical Co., Ltd.), the film in which pores are introduced, or lamination of the films is usable.

Next, as shown in FIG. 1B, a cap film 13 is formed, for example, in a film thickness of 30 nm to 200 nm on the low-k dielectric film 12 by a CVD method. As the cap film 13, a SiO₂ film, a SiC film, a SiCN film, a SiCO film, a SiN film, or lamination of the films is usable.

Moreover, a groove 14 for damascene wiring is formed in the cap film 13, low-k dielectric film 12, and diffusion barrier film 11 by a lithography technique and dry etching. It is to be noted that the low-k dielectric film 12 of a substrate outer peripheral portion can be removed during the dry etching for working the groove 14 for this metal wiring. FIG. 2 is a process sectional view showing the case that the low-k dielectric film formed on outer peripheral portion of the substrate is removed by dry etching. As shown in FIG. 2, a resist pattern PR in which the substrate outer peripheral portion and the groove forming portion are opened is formed on the cap film 13, and the dry etching is performed using the resist pattern PR as a mask. Accordingly, the groove 14 is formed, and the low-k dielectric film 12 of the substrate outer peripheral portion is removed. In this case, the low-k dielectric film 12 does not have to be removed by the above-described chemical solution. This method is applicable to the removing of all the low-k dielectric films described hereinafter.

Next, a barrier metal film 15 is formed on an inner wall of the groove 14 and the cap film 13 by a sputtering method, and a seed Cu film is formed on the barrier metal film 15 by the sputtering method. As the barrier metal film 15, for example, a Ta film, a Ti film, a TaN film, a TiN film, a WN film, or a WSiN film, or lamination of the films is usable. Furthermore, a Cu film 16 is formed on a seed Cu film by the electrolytic plating method. Thereafter, annealing is performed. It is to be noted that the annealing may be performed after removing the Cu film 16 by the chemical solution. Accordingly, the groove 14 is filled with a conductive film constituted of the barrier metal film 15, the seed Cu film, and the Cu film 16. The film thickness of the Cu film 16 is preferably set to be about 1.5 times to twice the film thickness of the low-k dielectric film 12 in such a manner that the groove 14 is completely filled with the Cu film 16.

Next, as shown in FIG. 1C, the Cu film 16 (including the seed Cu film, and this also applies to the following) of the substrate outer peripheral portion is removed by the chemical solution. A removed width B of the Cu film 16, that is, a length from the substrate edge 10 to the Cu film 16 edge is set to be larger than the above-described removed width A by 1 mm or more.

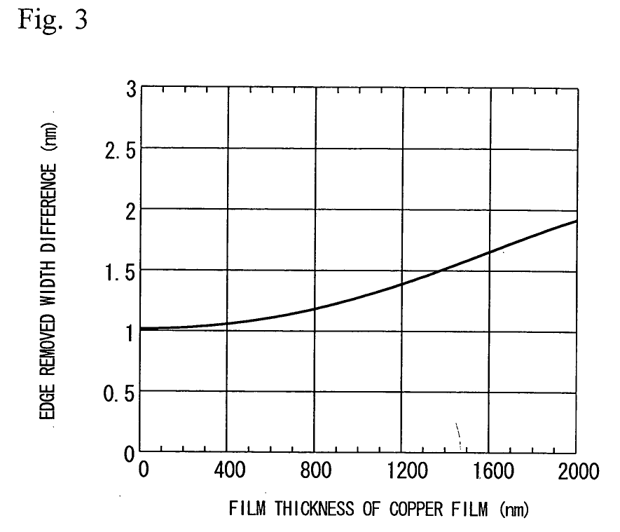

FIG. 3 is a diagram showing a relationship between the film thickness of the Cu film and an edge removed width difference “B-A” (described later) necessary for preventing the low-k dielectric film from being peeled. As shown in FIG. 3, when the film thickness of the Cu film 16 increases, the edge removed width difference needs to be increased in order to prevent the low-k dielectric film 12 from being peeled. For example, when the low-k dielectric film 12 having a Young's modulus of 2 GPa is used, and the film thickness of the Cu film 16 is 50 nm or more and less than 600 nm, the edge removed width difference is preferably set to 1 mm or more. When the film thickness is 600 nm or more and less than 900 nm, the edge removed width difference is preferably set to 1.3 mm or more. When the film thickness is 900 nm or more and less than 2000 nm, the edge removed width difference is preferably set to 1.5 mm or more. When the film thickness is 2000 nm or more, the edge removed width difference is preferably set to 2.0 mm or more.

Next, as shown in FIG. 1D, unnecessary portions of the Cu film 16 and barrier metal film 15 formed on the cap film 13 are removed using an orbital-type CMP apparatus (not shown). Since the removed width B is set to be larger than the removed width A by 1 mm or more as described above, a high CMP pressure can be prevented from being applied to the low-k dielectric film 12 edge. It is to be noted that the Cu film 16 left outside the low-k dielectric film 12 edge may be removed by the chemical solution.

A Cu damascene wiring is formed in the low-k dielectric film 12 through the above-described steps.

### EXAMPLE 1

Next, a wiring forming method according to First Embodiment will be described in more detail in accordance with Example 1. Example 1 will be described with reference to FIGS. 1A to 1D.

First, as shown in FIG. 1A, a SiC film 11 is formed in a film thickness of 50 nm on a silicon substrate 1 having a diameter of 300 mm by a CVD method. Subsequently, a MSQ film 12 is formed in a film thickness of 250 nm on the SiC film 11 by a spin coating method. A substrate rotation speed is set to 900 rpm. Immediately after applying the MSQ film 12, N-methyl-2-pyrrolidinone (CH₃NC₄H₆O) is dropped onto a wafer outer periphery, and the MSQ film 12 in a wafer edge portion is removed by a removed width A.

Here, the removed width A of the MSQ film 12 from a wafer edge 10 is changed and set in a range of 2 mm to 15 mm to thereby prepare 14 types of samples. All the samples are baked at 250° C. in a nitrogen atmosphere using a hot plate, and thereafter cured at 450° C. in the nitrogen atmosphere for ten minutes using the hot plate. Further samples having an equal removed width A are prepared in which a Young's modulus of the MSQ film 12 is changed to 14 GPa from 2 GPa every 1 GPa. The Young's modulus is changed by changing porosity of the MSQ film 12. It is to be noted that chemical composition of the MSQ film 12 is the same with respect to all the samples.

After baking and curing, these MSQ films 12 are irradiated with helium plasma using a CVD apparatus. Accordingly, the surfaces of the MSQ films 12 are reformed. Adhesion of the MSQ film 12 with respect to a SiO₂ film 13 described next can be improved by this He plasma process.

Next, as shown in FIG. 1B, the SiO₂ film 13 is formed in a film thickness of 50 nm on the MSQ film 12 by the CVD method. Subsequently, a groove 14 for a damascene wiring is formed in the SiO₂ film 13, MSQ film 12, and SiC film 11 by a lithography technique and dry etching. Next, a TaN film/Ta film 15 are formed in film thicknesses of 10 nm/15 nm in the groove 14 and on the SiO₂ film 13 by a sputtering method, and a seed Cu film (omitted from the drawing). This also applies to the following) is formed in a film thickness of 75 nm by the sputtering method. Moreover, the Cu film 16 is formed on the seed Cu film by an electrolytic plating method. Thereafter, annealing is performed at a temperature of 250° C. for 30 minutes.

Next, as shown in FIG. 1C, the Cu film 16 in the vicinity of the wafer edge 10 is removed from the wafer edge 10 by a removed width B using an aqueous solution containing 3% HF and 30% H₂O₂. The removed width B of the Cu film 16 is set to be larger than the removed width A of the MSQ film 12 by 1 mm.

Next, a shown in FIG. 1D, unnecessary portions of the Cu film 16 and TaN film/Ta film 15 on the SiO₂ film 13 are removed by a CMP process. An orbital-type CMP apparatus (e.g., Momentum 300 of Novellus Systems, Inc.) is used as a CMP apparatus, IC1000 by Rodel Nitta Company is used as a polishing pad, and a slurry (HS-C430-TU) free of abradant particles, manufactured by Hitachi Chemical Co., Ltd., is used as a CMP slurry. Polishing conditions are set to a CMP pressure of 1.5 psi, an orbital rotation speed of 600 rpm, a head rotation speed of 24 rpm, and a slurry supply speed of 300 cc/minute.

As a result of Cu-CMP performed on the conditions, it is found that when the removed width A of the MSQ film 12 is large, the MSQ film 12 can be prevented from being peeled at the time of the Cu-CMP. For example, the following result is obtained in the case of a sample having the MSQ film 12 having a Young's modulus of 3 GPa.

When the removed width A of the MSQ film 12 is 2 mm, the MSQ film 12 peels only 10 seconds immediately after starting the Cu-CMP. On the other hand, when the removed width A is 3 mm, the MSQ film 12 does not peel 50 seconds after starting the Cu-CMP. Furthermore, when the removed width A is 4 mm, the MSQ film 12 does not peel 100 seconds after starting the Cu-CMP. Furthermore, in a case where the removed width A lengthened to 5 mm, 6 mm, 7 mm, 8 mm, 9 mm, a time elapsed until the MSQ film 12 peeled after the start of the Cu-CMP lengthens to 500 seconds, 1000 seconds, 5000 seconds, 10000 seconds, and 50000 seconds. Moreover, when the removed width A is 10 mm or more, finally the MSQ film 12 does not peel.

Moreover, in the case of a sample having the MSQ film 12 having a Young's modulus of 10 GPa, when the removed width A of the MSQ film 12 is 3 mm or more, it is possible to prevent the MSQ film 12 from being peeled at the time of the Cu-CMP. Moreover, in a sample having the MSQ film 12 having a Young's modulus of 9 GPa, when the removed width A is 4 mm or more, it is possible to prevent the MSQ film 12 from being peeled at the time of the Cu-CMP. Furthermore, when the Young's modulus of the MSQ film 12 drops to 8 GPa, 7 GPa, 6 GPa, 5 GPa, 4 GPa, 3 GPa, and the removed width A is set to 5 mm or more, 6 mm or more, 7 mm or more, 8 mm or more, 9 mm or more, and 10 mm or more, it is possible to prevent the MSQ film 12 from being peeled at the time of the Cu-CMP.

Therefore, the removed width A is preferably set to 4 mm or more in consideration of the Young's modulus or the polishing time of the low-k dielectric film. From a viewpoint of yield of a chip, the removed width A is preferably set to 15 mm or less.

### EXAMPLE 2

In Example 1, as described above, the removed width B of the Cu film 16 is set to be larger than the removed width A of the MSQ film 12 by 1 mm. In Example 2, a removed width B of a Cu film 16 is relatively changed with respect to a removed width A of a MSQ film 12, and peeling of the MSQ film 12 in Cu-CMP is checked. Mainly respects different from those of Example 1 will be described hereinafter.

In Example 2, four types of samples are prepared in which the removed widths A of the MSQ films 12 from wafer edges 10 are set to 2 mm, 4 mm, 6 mm, 8 mm. In the same manner as in Example 1, further samples are prepared in which porosities of the MSQ films 12 are changed, accordingly removed widths A are set to be equal, and Young's modulus of the MSQ films 12 are changed to 14 GPa from 2 GPa every 1 GPa. More samples are prepared in which removed widths B of Cu films 16 are changed to 15 mm from 2 mm every 1 mm. Other methods are performed in the same manner as in Example 1.

In the Cu-CMP of the sample having the MSQ film 12 whose Young's modulus is 3 GPa for one minute, the following result is obtained.

It is found that a peeling area of the MSQ film 12 from the wafer edge 10 increases in a case where the removed width A of the MSQ film 12 is equal to the removed width B of the Cu film 16. When the removed width A, B is 2 mm, the peeling area is maximized. As the removed width A, B increased to 4 mm, 6 mm, 8 mm, the peeling area is reduced.

On the other hand, it is found that the MSQ film 12 is prevented from being peeled at the time of the Cu-CMP in a case where the removed width B of the Cu film 16 is set to be larger than the removed width A of the MSQ film 12 by 1 mm or more. When a difference (hereinafter referred to as the “edge removed width difference”) between the removed width A and the removed width B is 1 mm, it is possible to prevent the MSQ film 12 from being peeled during the Cu-CMP of a sample whose MSQ film 12 has a Young's modulus of 10 GPa. When the edge removed width difference is 2 mm, it is possible to prevent the MSQ film 12 from being peeled during the Cu-CMP of a sample whose MSQ film 12 has a Young's modulus of 6 GPa. Furthermore, as the edge removed width difference increases to 3 mm, 4 mm, 5 mm, it is possible to prevent the MSQ film 12 from being peeled during the Cu-CMP of samples whose MSQ films 12 has Young's moduli of 5 GPa, 4 GPa, 3 GPa.

As described above, in First Embodiment, the difference between the removed width A of the low-k dielectric film 12 and the removed width B of the Cu film 16 is set to 1 mm or more, and accordingly a distance between the low-k dielectric film 12 edge and the Cu film 16 edge is broadened as compared with a conventional technique. Accordingly, the CMP pressure applied to the low-k dielectric film 12 edge can be largely reduced in the Cu-CMP, and the low-k dielectric film 12 can be rapidly prevented from being peeled in the Cu-CMP. When the removed width A of the low-k dielectric film 12 is set to 4 mm or more, the low-k dielectric film 12 can further be prevented from being peeled.

It is to be noted that a similar result is obtained even when the present experiment is performed even with respect to a wafer on which a device is mounted. The present invention is applicable to not only a first Cu wiring layer but also a second or subsequent Cu wiring layer. Since the low-k dielectric film more easily peels in an upper wiring layer, the present invention is preferable especially in forming the upper Cu wiring layer.

Moreover, in First Embodiment, the low-k dielectric film coated with a single layer is used, but a laminate film of the applied low-k dielectric film and a low-k dielectric film formed by the CVD method may be used.

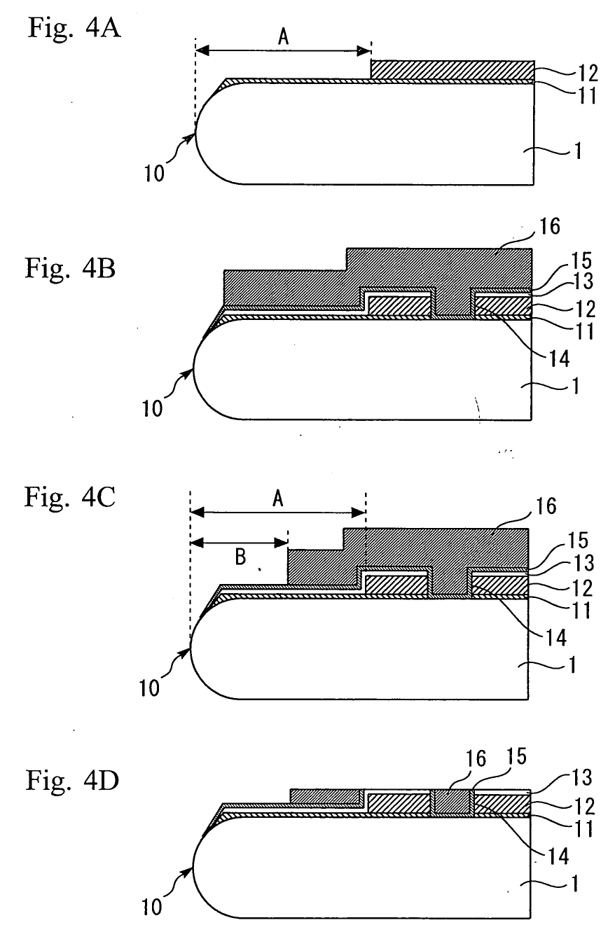

Second Embodiment In First Embodiment, the case where the removed width B of the Cu film 16 is set to be larger than the removed width A of the low-k dielectric film 12, that is, a case where the low-k dielectric film 12 edge is on the side of a substrate outer periphery from the Cu film 16 edge has been described. In Second Embodiment, a case where the removed width B of the Cu film 16 is set to be smaller than the removed width A of the low-k dielectric film 12, that is, a case where the low-k dielectric film 12 edge is on the side of a substrate center from the Cu film 16 edge will be described. Since other respects are similar to those of First Embodiment, different respects from First Embodiment will be mainly described with reference to FIGS. 4A to 4D. FIGS. 4A to 4D are process sectional views showing a method for forming a wiring according to Second Embodiment of the present invention.

First, as shown in FIGS. 4A and 4B, steps described in First Embodiment with reference to FIGS. 1A and 1B are performed.

Next, as shown in FIG. 4C, a Cu film 16 of a substrate outer peripheral portion is removed by a chemical solution. A removed width B of the Cu film 16 is set to be smaller than a removed width A of a low-k dielectric film 12 by 1 mm or more.

Thereafter, as shown in FIG. 4D, unnecessary portions of the Cu film 16 and barrier metal film 15 formed on a cap film 13 are removed using an orbital-type CMP apparatus in the same manner as in First Embodiment. As described above, since the removed width B is set to be smaller than the removed width A by 1 mm or more, a high CMP pressure can be prevented from being applied to the a low-k dielectric film 12 edge.

A Cu damascene wiring is formed in the low-k dielectric film 12 through the above-described steps.

Also in Second Embodiment, since a difference between the removed width A of the low-k dielectric film 12 and the removed width B of the Cu film 16 is set to 1 mm or more in the same manner as in First Embodiment, a distance between the low-k dielectric film 12 edge and Cu film 16 edge is broadened as compared with a conventional technique. Accordingly, the CMP pressure applied to the low-k dielectric film 12 edge can be largely reduced in the Cu-CMP, and the low-k dielectric film 12 can be rapidly prevented from being peeled in the Cu-CMP in the same manner as in First Embodiment. When the removed width A of the low-k dielectric film 12 is set to 4 mm or more, the low-k dielectric film 12 can further be prevented from being peeled.

Moreover, in Second Embodiment, the Cu film 16 edge is positioned outside the low-k dielectric film 12 edge at a time when the Cu film 16 is removed with a chemical solution. That is, the low-k dielectric film 12 edge is coated with the Cu film 16 in the Cu-CMP. Therefore, the low-k dielectric film 12 can further be prevented from being peeled in the Cu-CMP by an anchor effect as compared with First Embodiment.

Third Embodiment

In Third Embodiment of the present invention, the wiring forming method of First Embodiment described above is applied to a Cu wiring serving as a first conductive layer of a semiconductor device.

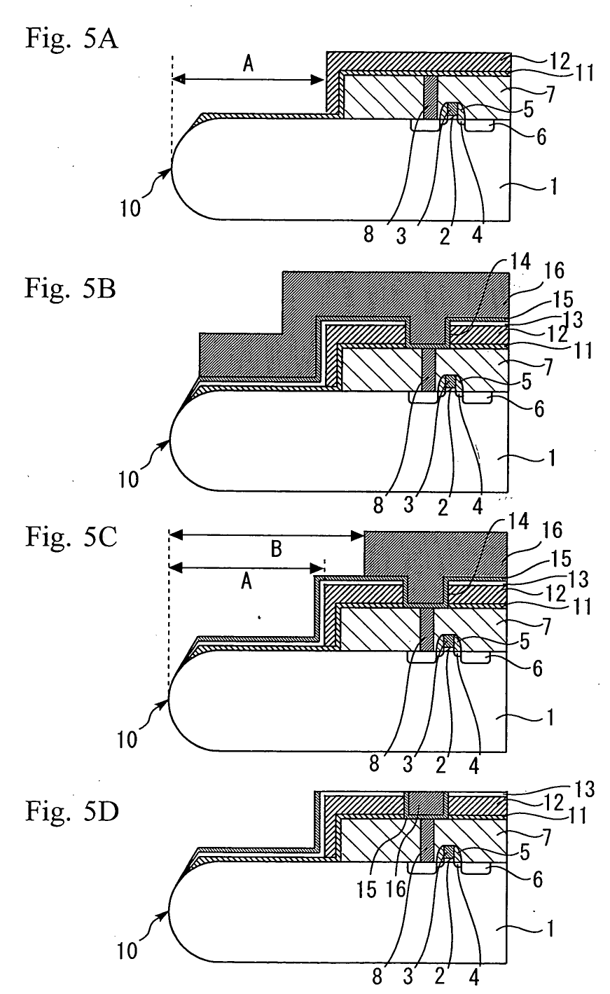

FIGS. 5A to 5D are process sectional views showing a method of manufacturing a semiconductor device according to Third Embodiment of the present invention.

First, as shown in FIG. 5A, a semiconductor element having a diffusion layer, such as a MIS transistor, is formed on a substrate 1. Although detailed description is omitted, a gate insulating film 2 and a conductive film 3 are formed on a silicon substrate serving as the substrate 1, and thereafter these films 2, 3 are patterned to form a gate electrode 3. Impurities are implanted into the substrate 1 using the gate electrode 3 as a mask to thereby form low-concentration diffusion layers (extension regions) 4, and side walls 5 are formed on opposite sides of the gate electrode 3. The impurities are implanted into the substrate 1 using the side walls 5 and the gate electrode 3 as masks to thereby form a high-concentration diffusion layers (source/drain regions) 6.

An insulating film 7 is formed so as to cover the transistor formed by performing the above-described steps, and a contact 8 to be connected to the high-concentration diffusion layers 6 is formed in the insulating film 7.

Next, a diffusion barrier film 11 is formed, for example, in a film thickness of 30 nm to 200 nm on the insulating film 7 and the contact 8 by a CVD method.

Next, immediately after a low-k dielectric film 12 is formed, for example, in a film thickness of 100 nm to 1000 mm on the diffusion barrier film 11 by a spin coating method, the low-k dielectric film 12 of a substrate outer peripheral portion is removed by a chemical solution by a width A. The removed width A, that is, a length from a substrate edge 10 to a low-k dielectric film 12 edge is preferably 3 mm or more. After removing the low-k dielectric film 12, baking and curing are performed in an inactive gas atmosphere, and further He plasma is applied to thereby reform the surface of the low-k dielectric film 12.

Next, as shown in FIG. 5B, a cap film 13 is formed, for example, in a film thickness of 30 nm to 200 nm on the low-k dielectric film 12 by the CVD method.

Moreover, a groove 14 for damascene wiring is formed in the cap film 13, low-k dielectric film 12, and diffusion barrier film 11 by a lithography technique and dry etching. Moreover, a barrier metal film 15 is formed on inner walls of the groove 14 and the cap film 13 by a sputtering method, and a seed Cu film is formed on the barrier metal film 15 by the sputtering method. Furthermore, a Cu film 16 is formed on the seed Cu film by an electrolytic plating method. Thereafter, annealing is performed. Accordingly, the groove 14 is filled with a conductive film constituted of the barrier metal film 15, seed Cu film, and Cu film 16. It is to be noted that the annealing may be performed after removing the Cu film 16 with a chemical solution.

Next, as shown in FIG. 5C, the Cu film 16 of the substrate outer peripheral portion is removed by the chemical solution. A removed width B of the Cu film 16, that is, a length from the substrate edge 10 to the Cu film 16 edge is set to be larger than the above-described removed width A by 1 mm or more.

Next, as shown in FIG. 5D, unnecessary portions of the Cu film 16 and barrier metal film 15 formed on the cap film 13 are removed using an orbital-type CMP apparatus in the same manner as in First Embodiment. A Cu damascene wiring serving as a first conductive layer electrically connecting to the diffusion layer 6 via the contact 8 is formed through the above-described steps.

As described above, according to Third Embodiment, when a difference between the removed width A of the low-k dielectric film 12 and the removed width B of the Cu film 16 is set to 1 mm or more, a distance between the low-k dielectric film 12 edge and the Cu film 16 edge is broadened as compared with a conventional technique. Accordingly, a CMP pressure applied to the low-k dielectric film 12 edge can be largely reduced in the Cu-CMP for the first conductive layer, and the low-k dielectric film 12 can be rapidly prevented from being peeled in the Cu-CMP. When the removed width A of the low-k dielectric film 12 is set to 4 mm or more, the low-k dielectric film 12 can further be prevented from being peeled. Therefore, yield of the semiconductor device can be enhanced, and reliability of the semiconductor device can be improved.

It is to be noted that Third Embodiment is applicable to not only a first Cu wiring layer but also a second or subsequent Cu wiring layer. Since the low-k dielectric film more easily peels in an upper wiring layer, the present invention is preferable especially in forming the upper Cu wiring layer (this also applies to Fifth Embodiment described later).

Fourth Embodiment

In Third Embodiment described above, the wiring forming method of First Embodiment is applied to a Cu wiring serving as the first conductive layer of a semiconductor device. In Fourth Embodiment, the wiring forming method of First Embodiment is applied to a Cu wiring serving as a first conductive layer of a liquid crystal display device.

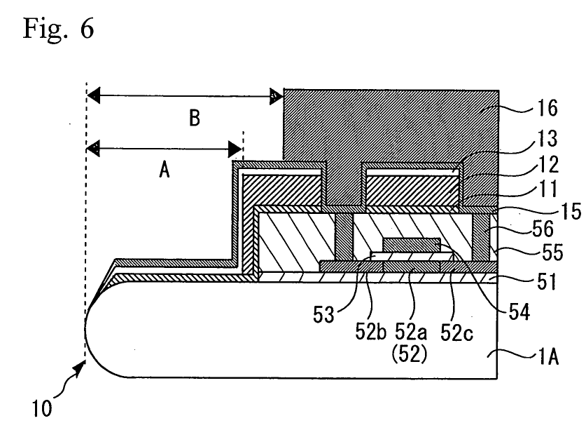

FIG. 6 is a process sectional view showing a method of manufacturing a liquid crystal display device according to Fourth Embodiment of the present invention.

First, a thin-film transistor (TFT) is formed on a glass substrate 1A. Concretely, an undercoat insulating film 51 is formed on the glass substrate 1A, and a poly-silicon film 52 is formed on the undercoat insulating film 51. A gate insulating film 53 is formed on the poly-silicon film 52, and a gate electrode 54 constituted of a conductive film is formed on the gate insulating film 53. Next, impurities are implanted into the poly-silicon film 52 using the gate electrode 54 as a mask, and thereafter heat treatment is performed to thereby form a source region 52b and a drain region 52c on opposite sides of a channel region 52a of the poly-silicon film 52. Moreover, a protective film 55 is formed as an interlayer insulating film on the whole surface of the substrate. Furthermore, contact plugs 56 to be connected to the source region 52b and the drain region 52c, respectively, are formed in the protective film 55. Although description is omitted, the wiring according to First Embodiment is applicable onto the protective film 55.

It is to be noted that a wiring structure applied to a semiconductor device in an embodiment described later is also applicable to the liquid crystal display device as described in Third Embodiment.

Fifth Embodiment

In Fifth Embodiment of the present invention, the above-described wiring forming method of Second Embodiment is applied to a Cu wiring serving as a first conductive layer of a semiconductor device.

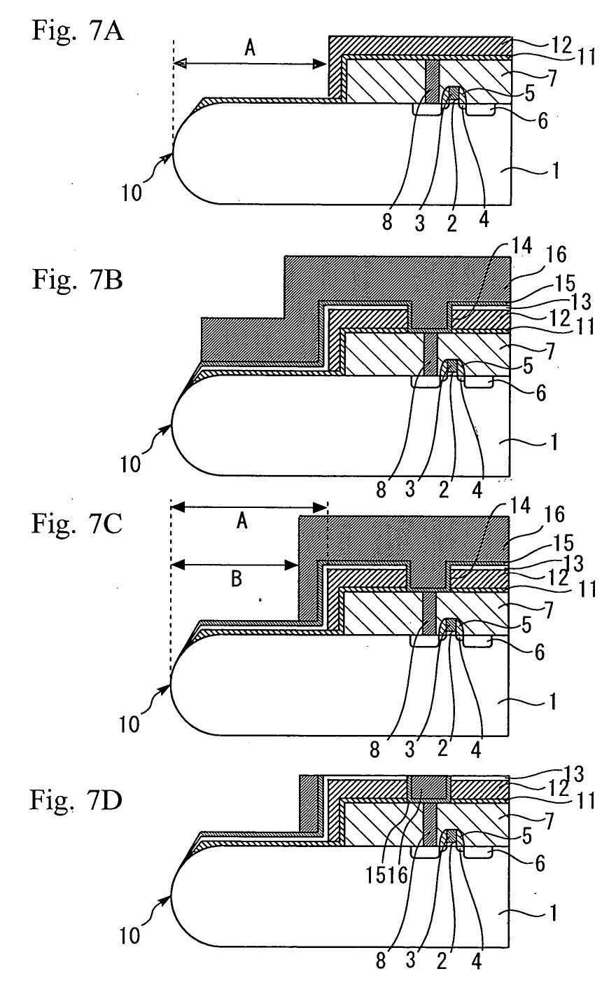

In Third and Fourth Embodiments described above, the case where the removed width B of the Cu film 16 is set to be larger than the removed width A of the low-k dielectric film 12, that is, a case where a low-k dielectric film 12 edge is on the side of a substrate outer periphery from a Cu film 16 edge has been described. In Fifth Embodiment, a case where the removed width A of the low-k dielectric film 12 is set to be larger than the removed width B of the Cu film 16, that is, a case where the low-k dielectric film 12 edge is on the side of a substrate center from the Cu film 16 edge will be described. Since other respects are similar to those of Third Embodiment, different respects from Third Embodiment will be mainly described with reference to FIGS. 7A to 7D. FIGS. 7A to 7D are process sectional views showing a method of manufacturing a semiconductor device according to Fifth Embodiment of the present invention.

First, as shown in FIGS. 7A, B, steps described in Third Embodiment with reference to FIGS. 5A, B are performed.

Next, as shown in FIG. 7C, a Cu film 16 of a substrate outer peripheral portion is removed by a chemical solution. A removed width B of the Cu film 16 is set to be smaller than a removed width A of a low-k dielectric film 12 by 1 mm or more.

Thereafter, as shown in FIG. 7D, unnecessary portions of the Cu film 16 and barrier metal film 15 formed on a cap film 13 are removed using an orbital-type CMP apparatus in the same manner as in First Embodiment. As described above, since the removed width B is set to be smaller than the removed width A by 1 mm or more, a high CMP pressure can be prevented from being applied to the a low-k dielectric film 12 edge.

A Cu damascene wiring is formed in the low-k dielectric film 12 through the above-described steps.

Also in First Embodiment, since a difference between the removed width A of the low-k dielectric film 12 and the removed width B of the Cu film 16 is set to 1 mm or more in the same manner as in Third Embodiment, a distance between the low-k dielectric film 12 edge and Cu film 16 edge is broadened as compared with a conventional technique. Accordingly, the CMP pressure applied to the low-k dielectric film 12 edge can be largely reduced in the Cu-CMP for a first conductive layer, and the low-k dielectric film 12 can be rapidly prevented from being peeled in the Cu-CMP. When the removed width A of the low-k dielectric film 12 is set to 4 mm or more, the low-k dielectric film 12 can further be prevented from being peeled. Therefore, yield of the semiconductor device can be enhanced, and reliability of the semiconductor device can be improved.

Moreover, in First Embodiment, the Cu film 16 edge is positioned outside the low-k dielectric film 12 edge at a time when the Cu film 16 is removed with a chemical solution. That is, the low-k dielectric film 12 edge is coated with the Cu film 16 in the Cu-CMP. Therefore, the low-k dielectric film 12 can further be prevented from being peeled in the Cu-CMP by an anchor effect as compared with Third Embodiment.

Sixth Embodiment

In Sixth Embodiment of the present invention, the above-described wiring forming method of First Embodiment is applied to a Cu wiring of a semiconductor mounted device. Concretely, the embodiment is applied to the Cu wiring on the semiconductor chip, when packaging a semiconductor chip into a module.

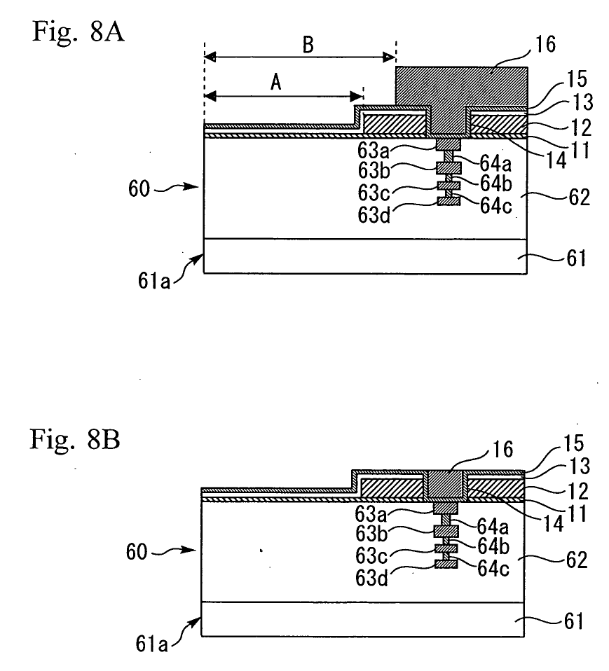

FIGS. 8A and 8B are process sectional views showing a method of manufacturing a semiconductor mounted device according to Sixth Embodiment of the present invention.

First, as shown in FIG. 8A, a semiconductor chip (semiconductor device) 60 is formed comprising a multilayered wiring structure 62 having multilevel wiring layers 63a, 63b, 63c, 63d, and via-contacts 64a, 64b, 64c which connect the layers to one another in an insulating film on a substrate 61. It is to be noted that a semiconductor element (e.g., MIS transistor) in the multilayered wiring structure,62 is described in Fourth Embodiment, and therefore drawing and description are omitted.

Next, a diffusion barrier film 11 is formed, for example, in a film thickness of 30 nm to 200 nm on the multilayered wiring structure 62 by a CVD method.

Next, immediately after a low-k dielectric film 12 is formed, for example, in a film thickness of 100 nm to 1000 mm on the diffusion barrier film 11 by a spin coating method, the low-k dielectric film 12 of a substrate outer peripheral portion is removed by a width A by a chemical solution. A removed width A, that is, a length from a substrate edge 61a to the edge of the low-k dielectric film 12 is preferably 3 mm or more. After removing the low-k dielectric film 12, baking and curing are performed in an inactive gas atmosphere, and further the surface of the low-k dielectric film 12 is reformed by irradiation with He plasma.

Next, a cap film 13 is formed, for example, in a film thickness of 30 nm to 200 nm on the low-k dielectric film 12 by a CVD method.

Moreover, a groove 14 for damascene wiring is formed in the cap film 13, low-k dielectric film 12, and diffusion barrier film 11 by a lithography technique and dry etching. Moreover, a barrier metal film 15 is formed on an inner wall of the groove 14 and the cap film 13 by a sputtering method, and a seed Cu film is formed on the barrier metal film 15 by the sputtering method. Furthermore, a Cu film 16 is formed on the seed Cu film by an electrolytic plating method. Thereafter, annealing is performed. Accordingly, the groove 14 is filled with a conductive film constituted of the barrier metal film 15, the seed Cu film, and the Cu film 16. It is to be noted that the annealing may be performed after removing the Cu film 16 by the chemical solution.

Next, the Cu film 16 of the substrate outer peripheral portion is removed by the chemical solution. A removed width B of the Cu film 16, that is, a length from the substrate edge 61a to the Cu film 16 edge is set to be larger than the above-described removed width A by 1 mm or more.

Next, as shown in FIG. 8B, unnecessary portions of the Cu film 16 and barrier metal film 15 formed on the cap film 13 are removed using an orbital-type CMP apparatus (not shown) in the same manner as in First Embodiment. A Cu damascene wiring to be electrically connected to the wiring layer 63a is formed on the semiconductor chip 60 through the above-described steps.

As described above, in Sixth Embodiment, a difference between the removed width A of the low-k dielectric film 12 and the removed width B of the Cu film 16 is set to 1 mm or more, and accordingly a distance between the low-k dielectric film 12 edge and Cu film 16 edge is broadened as compared with a conventional technique. Accordingly, the CMP pressure applied to the low-k dielectric film 12 edge can be largely reduced in the Cu-CMP for a Cu wiring formed on the semiconductor chip 60, and the low-k dielectric film 12 can be rapidly prevented from being peeled in the Cu-CMP. When the removed width A of the low-k dielectric film 12 is set to 4 mm or more, the low-k dielectric film 12 can further be prevented from being peeled. Therefore, yield of the semiconductor mounted device can be enhanced, and reliability of the semiconductor mounted device can be improved.

It is to be noted that in Sixth Embodiment the case where the Cu wiring layer serving as the first conductive layer on the semiconductor chip 60 is formed has been described, but the present invention is also applicable to a case where multilevel Cu wiring layers are formed. Since the low-k dielectric film more easily peels in an upper wiring layer, the present invention is preferable especially in forming the upper Cu wiring layer (this also applies to Seventh Embodiment described later).

Seventh Embodiment

In Seventh Embodiment of the present invention, the above-described wiring forming method of Second Embodiment is applied to a Cu wiring of a semiconductor mounted device.

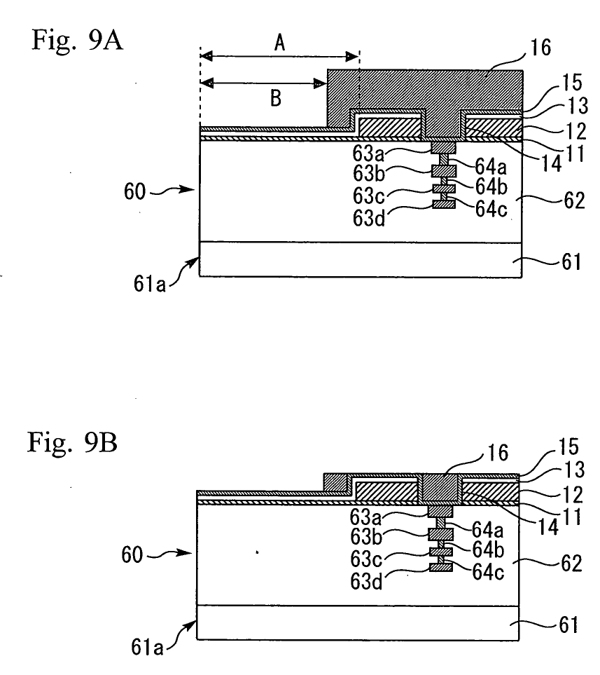

In Sixth Embodiment described above, the case where the removed width B of the Cu film 16 is set to be larger than the removed width A of the low-k dielectric film 12, that is, a case where a low-k dielectric film 12 edge is on the side of a substrate outer periphery from a Cu film 16 edge has been described. In Seventh Embodiment, a case where the removed width A of the low-k dielectric film 12 is set to be larger than the removed width B of the Cu film 16, that is, a case where the low-k dielectric film 12 edge is on the side of a substrate center from the Cu film 16 edge will be described. Since other respects are similar to those of Sixth Embodiment, different respects from Sixth Embodiment will be mainly described with reference to FIGS. 9A and 9B. FIGS. 9A and 9B are process sectional views showing a method of manufacturing a semiconductor mounted device according to Seventh Embodiment of the present invention.

First, as shown in FIG. 9A, a Cu film 16 is formed using a method similar to that of Sixth Embodiment.

Next, the Cu film 16 of a substrate outer peripheral portion is removed by a chemical solution. A removed width B of the Cu film 16 is set to be smaller than a removed width A of a low-k dielectric film 12 by 1 mm or more.

Thereafter, as shown in FIG. 9B, unnecessary portions of the Cu film 16 and barrier metal film 15 formed on a cap film 13 are removed using an orbital-type CMP apparatus in the same manner as in First Embodiment. As described above, since the removed width B is set to be smaller than the removed width A by 1 mm or more, a high CMP pressure can be prevented from being applied to the a low-k dielectric film 12 edge.

A Cu damascene wiring to be electrically connected to a wiring layer 63a is formed on a semiconductor chip 60 through the above-described steps.

Also in Seventh Embodiment, since a difference between the removed width A of the low-k dielectric film 12 and the removed width B of the Cu film 16 is set to 1 mm or more in the same manner as in Sixth Embodiment, a distance between the low-k dielectric film 12 edge and Cu film 16 edge is broadened as compared with a conventional technique. Accordingly, in the same manner as in Sixth Embodiment, the CMP pressure applied to the low-k dielectric film 12 edge can be largely reduced in the Cu-CMP for a Cu wiring formed on the semiconductor chip 60, and the low-k dielectric film 12 can be rapidly prevented from being peeled in the Cu-CMP. When the removed width A of the low-k dielectric film 12 is set to 4 mm or more, the low-k dielectric film 12 can further be prevented from being peeled. Therefore, yield of the semiconductor mounted device can be enhanced, and reliability of the semiconductor mounted device can be improved.

Moreover, in Seventh Embodiment, the Cu film 16 edge is positioned outside the low-k dielectric film 12 edge at a time when the Cu film 16 is removed with a chemical solution. That is, the low-k dielectric film 12 edge is coated with the Cu film 16 in the Cu-CMP. Therefore, the low-k dielectric film 12 can further be prevented from being peeled in the Cu-CMP by an anchor effect as compared with Sixth Embodiment.

Eighth Embodiment

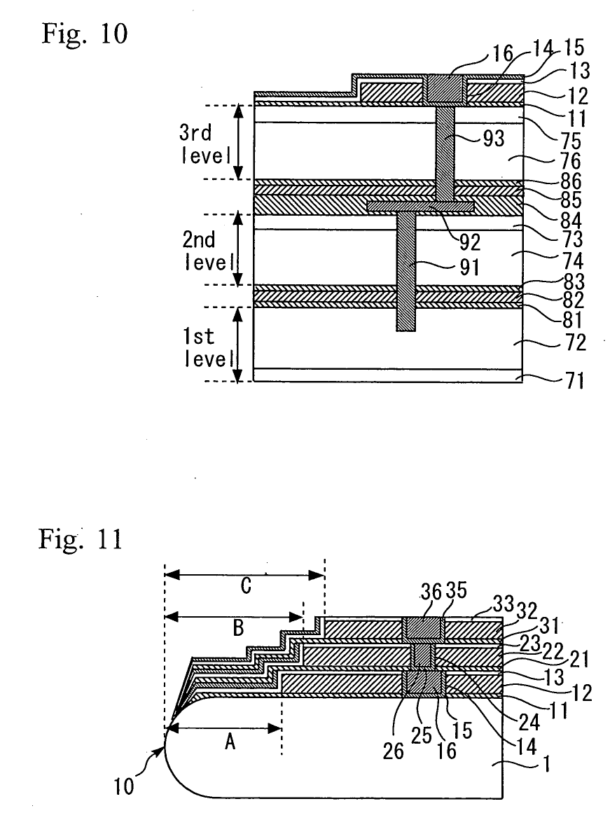

In Eighth Embodiment of the present invention, the above-described wiring forming method of First or Second Embodiment is applied to a Cu wiring of a semiconductor mounted device comprising multilevel substrates. FIG. 10 is a sectional view showing the semiconductor mounted device according to Eighth Embodiment.

As shown in FIG. 10, in the semiconductor mounted device, a first-level semiconductor chip (hereinafter referred to simply as the “chip”) having a substrate 71 and a multilayered wiring structure 72, a second-level chip having a substrate 73 and a multilayered wiring structure 74, and a third-level chip having a substrate 75 and a multilayered wiring structure 76 are stacked. The first-level chip is face-to-face connected to the second-level chip using a low-k dielectric film 82 as an adhesive layer, and the second-level chip is face-to-face connected to the third-level chip using a low-k dielectric film 85 as an adhesive layer. Insulating layers 81, 83 and insulating layers 84, 86 functioning as diffusion barrier films are formed in lower and uppers of the low-k dielectric films 82, 85, respectively. A wiring layer 92 is formed in the insulating film 84. A bridge via-contact 91 to be connected to the wiring layer 92 is formed in the first and second level chips, a bridge via-contact 93 is formed in the third-level chip, and accordingly the chips stacked in the three levels are electrically connected to one another.

A Cu damascene wiring to be electrically connected to the bridge via-contact 93 is formed on the third-level chip using a method similar to the above-described method of Sixth and Seventh Embodiments.

Also in Eighth Embodiment, since a difference between the removed width A of the low-k dielectric film 12 and the removed width B of the Cu film 16 is set to 1 mm or more in the same manner as in Sixth and Seventh Embodiments, a CMP pressure applied to a low-k dielectric film 12 edge can be largely reduced in Cu-CMP for a Cu wiring formed on the third-level chip, and the low-k dielectric film 12 can be rapidly prevented from being peeled in the Cu-CMP. When the removed width A of the low-k dielectric film 12 is set to 4 mm or more, the low-k dielectric film 12 can further be prevented from being peeled. Therefore, yield of the semiconductor mounted device can be enhanced, and reliability of the semiconductor mounted device can be improved.

Ninth Embodiment

FIG. 11 is a sectional view showing a multilayered wiring structure according to Ninth Embodiment of the present invention.

As shown in FIG. 11, a first diffusion barrier film 11 is formed on a substrate serving as an underlayer 1, and a first low-k dielectric film 12 having a dielectric constant of 3 or less is formed on the diffusion barrier film. Here, the first low-k dielectric film 12 is removed from a substrate edge 10 by a width A (e.g., 3 mm). As the substrate 1, for example, a printed board, a semiconductor chip (described later) or the like is usable besides a substrate such as a silicon substrate. As the first diffusion barrier film 11, for example, a SiO₂ film, a SiC film, a SiCN film, a SiCO film, or a SiN film is usable (this also applies to diffusion barrier films 21, 31 described later). As the first low-k dielectric film 12, for example, a methyl silsesquioxane (MSQ) film, a hydrogen silsesquioxane (HSQ) film, a polymer (e.g., SiLK (registered trademark manufactured by Dow Chemical Co. , Ltd. ), the film in which pores are introduced, or lamination of the films is usable (this also applies to low-k dielectric films 22, 32 described later).

A first cap film 13 for preventing plasma damages is formed on the first low-k dielectric film 12. As the first cap film 13, a SiO₂ film, a SiC film, a SiCN film, a SiCO film, or a SiN film, or lamination of the films is usable (this also applies to cap films 23, 33 described later).

An opening 14 is formed in the first cap film 13, the first low-k dielectric film 12, and the first diffusion barrier film 11, and a barrier metal film 15 is formed on the inner wall of the opening 14. Furthermore, a metal film 16 is formed on the barrier metal film 15. That is, since the opening 14 is filled with a conductive film constituted of the barrier metal film 15 and the metal film 16, a first conductive layer is formed in the opening 14. The opening 14 is a wiring groove, a via hole or the like (this also applies to openings 24, 34 described later). As the barrier metal film 15, for example, a Ta film, a Ti film, a TaN film, a TiN film, a WN film, or a WSiN film, or lamination of the films is usable (this also applies to barrier metal films 25, 35 described later). As the metal film 16, an Al film, a W film, a Cu film, or an alloy film of these metals is usable (this also applies to metal films 26, 36 described later).

A second diffusion barrier film 21 is formed on the first conductive layer and the first cap film 13, a second low-k dielectric film 22 is formed on the second diffusion barrier film 21, and further a second cap film 23 is formed on the second low-k dielectric film 22. Here, the second low-k dielectric film 22 is removed from a substrate edge 10 by a width B (e.g., 4 mm) larger than a removed width A of the first low-k dielectric film 12 by 0.4 mm or more. That is, the edge removed width B of the second low-k dielectric film 22 is larger than the edge removed width A of the first low-k dielectric film 12 by 0.4 mm or more. Accordingly, a second low-k dielectric film 22 edge is distant from a first low-k dielectric film 12 edge, and a CMP pressure can be prevented from being excessively concentrated on the first low-k dielectric film 12 edge during CMP of a metal film 26 described later. Details will be described later. A difference (hereinafter referred to as the “edge removed width difference”) between the removed width B and the removed width A is set to 0.7 mm or more, 1.0 mm or more in consideration of a relation with respect to an acquired region of an LSI chip. The difference set to be large in this manner is effective in preventing the low-k dielectric film from being peeled in the Cu-CMP.

Moreover, it is optimum to change the edge removed width difference in accordance with the film thickness of the low-k dielectric film. A film thickness of the low-k dielectric film usually for use is in a range of 150 nm to 2000 nm, and generally increases toward an upper.

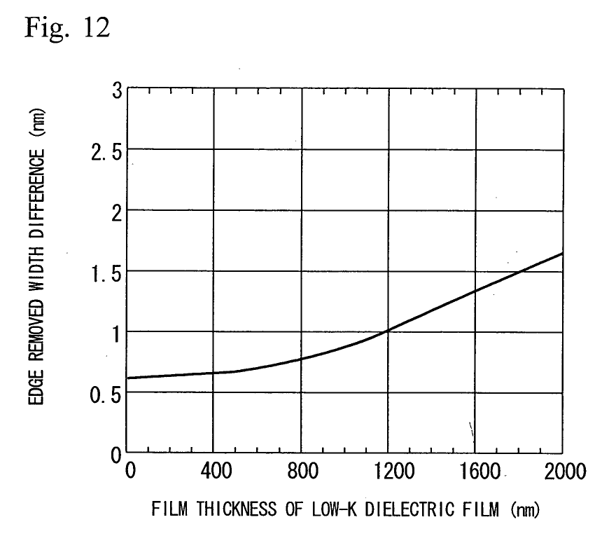

FIG. 12 is a diagram showing a relationship between the film thickness of the low-k dielectric film and an edge removed width difference necessary for preventing the low-k dielectric film from being peeled. Here, the low-k dielectric film has a Young's modulus of 2 GPa. Assuming that a low-k dielectric film having a Young's modulus of 2 GPa or more and less than 4 GPa is used, as shown in FIG. 12, when the film thickness of the low-k dielectric film (22) is 10 nm or more and less than 500 nm, the edge removed width difference is preferably set to 0.7 mm or more. When the film thickness is 500 nm or more and less than 800 nm, the edge removed width difference is preferably set to 0.8 mm or more. When the film thickness is 800 nm or more and less than 2000 nm, the edge removed width difference is preferably set to 1.2 mm or more. When the film thickness is 2000 nm or more, the edge removed width difference is preferably set to 1.5 mm or more.

Moreover, assuming that a low-k dielectric film having a Young's modulus of 4 GPa or more is used, when the film thickness of the low-k dielectric film is less than 300 nm, the edge removed width difference is preferably set to 0.4 mm or more. When the film thickness is 300 nm or more and less than 600 nm, the edge removed width difference is preferably set to 0.7 mm or more. When the film thickness is 600 nm or more, the edge removed width difference is preferably set to 1.0 mm or more.

Furthermore, an opening 24 is formed in the second cap film 23, the second low-k dielectric film 22, the second diffusion barrier film 21, and a barrier metal film 25 is formed on the inner wall of the opening 24, and further a metal film 26 is formed on the barrier metal film 25. That is, since the opening 24 is filled with a conductive film constituted of the barrier metal film 25 and the metal film 26, a second conductive layer is formed in the opening 24. The second conductive layer is connected to the first conductive layer.

A third diffusion barrier film 31 is formed on the second conductive layer and the second cap film 23, a third low-k dielectric film 32 is formed on the diffusion barrier film, and further a third cap film 33 is formed on the low-k dielectric film. Here, the third low-k dielectric film 32 is removed from a substrate edge 10 by a width C (e.g., 5 mm) larger than a removed width B of the second low-k dielectric film 22 by 0.4 mm or more. That is, the edge removed width C of the third low-k dielectric film 32 is larger than the edge removed width B of the second low-k dielectric film 22 by 0.4 mm or more. Accordingly, a third low-k dielectric film 32 edge is distant from a second low-k dielectric film 22 edge and the first low-k dielectric film 12 edge, and a CMP pressure can be prevented from being excessively concentrated on the second low-k dielectric film 22 edge and the first low-k dielectric film 12 edge during CMP of a metal film 36 described later.

Furthermore, an opening 34 is formed in the third cap film 33, the third low-k dielectric film 32, and the third diffusion barrier film 31, a barrier metal film 35 is formed on the inner wall of the opening 34, and further a metal film 36 is formed on the barrier metal film 35. That is, since the opening 34 is filled with a conductive film constituted of the barrier metal film 35 and the metal film 36, a third conductive layer is formed in the opening 34. The third conductive layer is connected to the second conductive layer.

Next, a method of forming the multilayered wiring structure will be described.

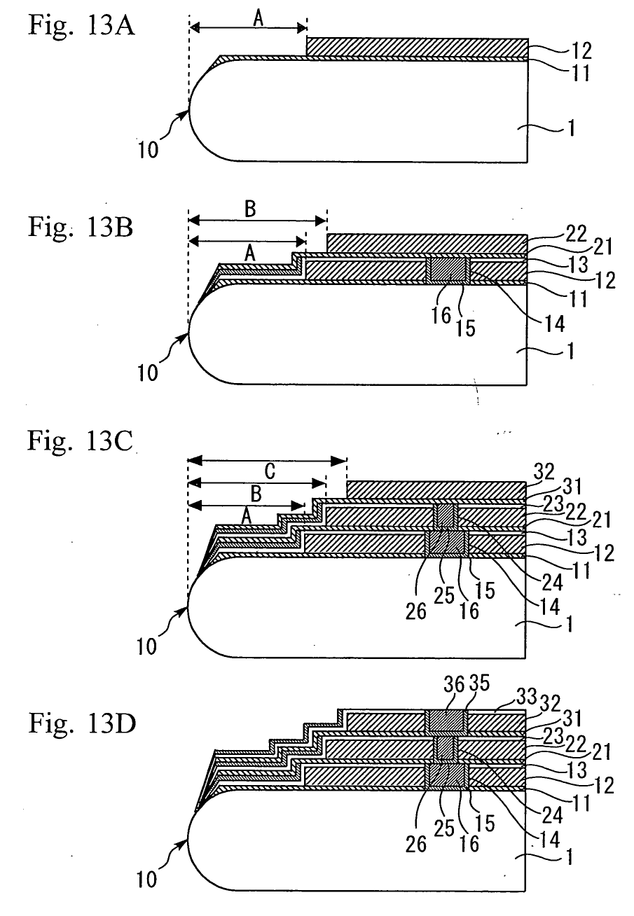

FIGS. 13A to 13D are process sectional views showing a method of forming a multilayered wiring according to Ninth Embodiment.

First, as shown in FIG. 13A, the first diffusion barrier film 11 is formed, for example, in a film thickness of 30 nm to 200 nm on the substrate 1 by a CVD method.

Next, immediately after the first low-k dielectric film 12 is formed, for example, in a film thickness of 100 nm to 1000 nm on the first diffusion barrier film 11 by a spin coating method, the first low-k dielectric film 12 of a substrate outer peripheral portion is removed by a chemical solution by a width A. The removed width A, that is, the length from a substrate edge 10 to the edge of the first low-k dielectric film 12 is, for example, 3 mm. After removing the first low-k dielectric film 12 by the chemical solution, baking and curing are performed in an inactive gas atmosphere, and further the surface of the first low-k dielectric film 12 is reformed by irradiation with He plasma.

Next, as shown in FIG. 13B, a first cap film 13 is formed, for example, in a film thickness of 30 nm to 200 nm on the first low-k dielectric film 12 by a CVD method. Moreover, an opening 14 is formed in the first cap film 13, first low-k dielectric film 12, and first diffusion barrier film 11 by a lithography technique and dry etching. Next, a barrier metal film 15 is formed on an inner wall of the opening 14 and the first cap film 13 by a sputtering method, and a seed Cu film is formed on the barrier metal film 15 by the sputtering method. Furthermore, a Cu film 16 is formed on a seed Cu film by the electrolytic plating method. Thereafter, annealing is performed. Accordingly, the opening 14 is filled with a conductive film constituted of the barrier metal film 15, the seed Cu film, and the Cu film 16. It is to be noted that the annealing may be performed after removing the Cu film 16 by the chemical solution as described later.

Next, the Cu film 16 (including the seed Cu film, and this also applies to the following) of the substrate outer peripheral portion is removed by the chemical solution. A removed width of the Cu film 16, that is, a length from the substrate edge 10 to the Cu film 16 edge is set to 2 mm which is smaller than the above-described removed width A of the above-described first low-k dielectric film 12 by 1 mm.

Next, unnecessary portions of the Cu film 16 and barrier metal film 15 formed on the first cap film 13 are removed using an orbital-type CMP apparatus (not shown) of. That is, the Cu film 16 and the barrier metal film 15 are removed using the first cap film 13 as a stopper film by a CMP process. Accordingly, a Cu wiring layer is formed as a first conductive layer.

Next, the second diffusion barrier film 21 is formed, for example, in a film thickness of 30 nm to 200 nm on the first cap film 13 and Cu wiring by the CVD method. Next, immediately after the second low-k dielectric film 22 is formed, for example, in a film thickness of 100 nm to 1000 nm on the second diffusion barrier film 21 by the spin coating method, the second low-k dielectric film 22 of a substrate outer peripheral portion is removed by a chemical solution by a width B. The removed width B of the second low-k dielectric film 22 is, for example, 4 mm which is larger than the removed width A of the first low-k dielectric film 12 by 1 mm. Thereafter, the baking and curing are performed in the inactive gas atmosphere, and further the surface of the second low-k dielectric film 22 is reformed by irradiation with He plasma.

Next, as shown in FIG. 13C, a second cap film 23 is formed, for example, in a film thickness of 30 nm to 200 nm on the second low-k dielectric film 22 by the CVD method. Moreover, an opening 24 is formed in the second cap film 23, second low-k dielectric film 22, and second diffusion barrier film 21 by the lithography technique and dry etching. Next, a barrier metal film 25 is formed on an inner wall of the opening 24 and the second cap film 23 by the sputtering method, and a seed Cu film is formed on the barrier metal film 25 by the sputtering method. Furthermore, a Cu film 26 is formed on the seed Cu film by the electrolytic plating method. Thereafter, the annealing is performed. Accordingly, the opening 24 is filled with a conductive film constituted of the barrier metal film 25, the seed Cu film, and the Cu film 26.

Next, the Cu film 26 of the substrate outer peripheral portion is removed by the chemical solution. A removed width of the Cu film 26 is set, for example, to 2 mm which is smaller than the removed width B of the second low-k dielectric film 22 by 2 mm. Thereafter, the CMP is performed on conditions similar to those of the Cu wiring layer of the first conductive layer, and accordingly unnecessary portions of the Cu film 26 and barrier metal film 25 formed on the second cap film 23 are removed. Accordingly, a via layer is formed as a second conductive layer.

Next, the third diffusion barrier film 31 is formed, for example, in a film thickness of 30 nm to 200 nm on the second cap film 23 and the via layer by the CVD method. Moreover, immediately after the third low-k dielectric film 32 is formed, for example, in a film thickness of 100 nm to 1000 nm on the third diffusion barrier film 31 by the spin coating method, the third low-k dielectric film 32 of a substrate outer peripheral portion is removed by a chemical solution by a width C. The removed width C of the third low-k dielectric film 32 is, for example, 5 mm which is larger than the removed width B of the second low-k dielectric film 22 by 1 mm. Thereafter, the baking and curing are performed in the inactive gas atmosphere, and further the surface of the third low-k dielectric film 32 is reformed by irradiation with He plasma.

Next, as shown in FIG. 13D, a third cap film 33 is formed, for example, in a film thickness of 30 nm to 200 nm on the third low-k dielectric film 32 by the CVD method. Moreover, an opening 34 is formed in the third cap film 33, third low-k dielectric film 32, and third diffusion barrier film 31 by the lithography technique and dry etching. Next, a barrier metal film 35 is formed on an inner wall of the opening 34 and the third cap film 33 by the sputtering method, and a seed Cu film is formed on the barrier metal film 35 by the sputtering method. Furthermore, a Cu film 36 is formed on the seed Cu film by the electrolytic plating method. There after, the annealing is performed. Accordingly, the opening 34 is filled with a conductive film constituted of the barrier metal film 35, the seed Cu film, and the Cu film 36.

Next, the Cu film 36 of the substrate outer peripheral portion is removed by the chemical solution. A removed width of the Cu film 36 is set, for example, to 2 mm which is smaller than the removed width C of the third low-k dielectric film 32 by 3 mm. Thereafter, the CMP is performed on conditions similar to those of the Cu wiring layer of the first conductive layer, and accordingly unnecessary portions of the Cu film 36 and barrier metal film 35 formed on the second cap film 33 are removed. Accordingly, a Cu wiring layer is formed as a third conductive layer.

### EXAMPLE 1

Next, Ninth Embodiment will be further concretely described in accordance with Example 1. Example 1 will be described with reference to FIGS. 13A to 13D.

First, as shown in FIG. 13A, a SiC film 11 is formed in a film thickness of 50 nm on a silicon substrate 1 having a diameter of 300 mm by a CVD method. Subsequently, a MSQ film 12 is formed in a film thickness of 250 nm on the SiC film 11 by a spin coating method. A substrate rotation speed is set to 900 rpm. Immediately after applying the MSQ film 12, N-methyl-2-pyrrolidinone (CH₃NC₄H₆O) is dropped onto a wafer outer periphery, and the MSQ film 12 in a substrate edge portion is removed by a removed width A. The removed width A of the MSQ film 12 is set to 3 mm. Thereafter, baking is performed at 250° C. in a nitrogen atmosphere using a hot plate, and curing is performed at 450° C. in the same atmosphere for 15 minutes.

Here, samples are prepared in which a Young's modulus of the MSQ film 12 is changed to 14 GPa from 2 GPa every 1 GPa. The Young's modulus is changed by changing porosity of the MSQ film 12. It is to be noted that chemical composition of the MSQ film 12 is the same with respect to all the samples.

These MSQ films 12 are irradiated with helium plasma using a CVD apparatus. Accordingly, the surfaces of the MSQ films 12 are reformed. Adhesion of the MSQ film 12 with respect to a SiO₂ film 13 described next can be improved by this He plasma process.

Next, as shown in FIG. 13B, the SiO₂ film 13 is formed in a film thickness of 50 nm on the MSQ film 12 by the CVD method. Subsequently, a wiring groove 14 is formed in the SiO₂ film 13, MSQ film 12, and SiC film 11 by a lithography technique and dry etching. Next, a TaN film/Ta film 15 are formed in film thicknesses of 10 nm/15nm in the wiring groove 14 and on the SiO₂ film 13 by a sputtering method, and a seed Cu film (omitted from the drawing). This also applies to the following) is formed in a film thickness of 75 nm by the sputtering method. Moreover, the Cu film 16 is formed on the seed Cu film by an electrolytic plating method. Thereafter, annealing is performed at a temperature of 250° C. for 30 minutes.

Next, the Cu film 16 in the vicinity of the substrate edge 10 is removed using an aqueous solution containing 3% HF and 30% H₂O₂. Are moved width of the Cu film 16 is set to 2 mm which is smaller than the removed width A of the MSQ film 12 by 1 mm.

Next, unnecessary portions of the Cu film 16 and TaN film/Ta film 15 on the SiO₂ film 13 are removed by a CMP process. An orbital-type CMP apparatus (e.g., Momentum 300 of Novellus Systems, Inc.) is used as a CMP apparatus, a single layer of foamed urethane (e.g., IC1000 by Rodel Nitta Company) is used as a polishing pad, a slurry (e.g., HS-C430-TU manufactured by Hitachi Chemical Co., Ltd.) free of abradant particles is used as a CMP slurry for Cu, and a slurry (e.g., HS-T605 manufactured by Hitachi Chemical Co., Ltd.) of abradant particles is used as a CMP slurry for the TaN film/Ta film. Polishing conditions are set to a CMP pressure of 1.5 psi, an orbital rotation speed of 600 rpm, a head rotation speed of 24 rpm, and a slurry supply speed of 300 cc/minute. The CMP of the Cu film 16 and the TaN film/Ta film 15 is performed in two steps using the changed slurry. A Cu wiring layer is formed as a first conductive layer through the above-described steps.

Next, a SiC film 21 is formed in a film thickness of 50 nm by a CVD method. Subsequently, a MSQ film 22 is formed in a film thickness of 250nm on the SiC film by a spin coating method. A substrate rotation speed is set to 900 rpm in the same manner as in the forming of the MSQ film. Immediately after applying the MSQ film 22, N-methyl-2-pyrrolidinone (CH₃NC₄H₆O) is dropped onto a wafer outer periphery, and the MSQ film 22 in a substrate edge portion is removed by a removed width B. The removed width B of the MSQ film 22 is set to 4 mm which is larger than the removed width A (=3 mm) of the MSQ film 12 by 1 mm. Thereafter, the baking and curing are performed on conditions similar to those of the MSQ film 12, and the surface of the MSQ film 22 is reformed by He plasma treatment.

Next, as shown in FIG. 13C, the SiO₂ film 23 is formed in a film thickness of 50 nm on the MSQ film 22 by the CVD method, and a via hole 24 is formed in the SiO₂ film 23, MSQ film 22, and SiC film 21 by a lithography technique and dry etching. Next, a TaN film/Ta film 25 are formed in film thicknesses of 10 nm/15 nm in the hole 24 and on the SiO₂ film 23 by a sputtering method, and a seed Cu film is formed in a film thickness of 75 nm by the sputtering method. Moreover, the Cu film 26 is formed on the seed Cu film by an electrolytic plating method. Thereafter, the annealing is performed at a temperature of 250° C. for 30 minutes.

Next, the Cu film 26 in the vicinity of the substrate edge 10 is removed using an aqueous solution containing 3% HF and 30% H₂O₂. A removed width of the Cu film 26 is set to 2 mm which is smaller than the removed width B of the MSQ film 22 by 2 mm.

Next, unnecessary portions of the Cu film 26 and TaN film/Ta film 25 on the SiO₂film 23 are removed by a CMP process using the above-described polishing conditions. Accordingly, a via layer is formed as a second conductive layer.

Next, a SiC film 31 is formed in a film thickness of 50 nm by the CVD method, and a MSQ film 32 is formed in a film thickness of 250 nm on the SiC film by the spin coating method. Immediately after applying the MSQ film 32, N-methyl-2-pyrrolidinone (CH₃NC₄H₆O) is dropped onto a wafer outer periphery, and the MSQ film 32 in a substrate edge portion is removed by a removed width C. The removed width C of the MSQ film 32 is set to 5 mm which is larger than the removed width B (=4 mm) of the MSQ film 22 by 1 mm. Thereafter, the baking and curing are performed on conditions similar to those of the MSQ films 12, 22, and the surface of the MSQ film 32 is reformed by the He plasma treatment.

Next, as shown in FIG. 13D, a SiO₂ film 33 is formed in a film thickness of 50 nm on the MSQ film 32 by the CVD method, and a via hole 34 is formed in the SiO₂ film 33, MSQ film 32, and SiC film 31 by the lithography technique and dry etching. Next, a TaN film/Ta film 35 are formed in film thicknesses of 10 nm/15 nm in the hole 34 and on the SiO₂ film 33 by the sputtering method, and a seed Cu film is formed in a film thickness of 75 nm by the sputtering method. Moreover, the Cu film 36 is formed on the seed Cu film by the electrolytic plating method. Thereafter, the annealing is performed at a temperature of 250° C. for 30 minutes.

Next, the Cu film 36 in the vicinity of the substrate edge 10 is removed using an aqueous solution containing 3% HF and 30% H₂O₂. A removed width of the Cu film 36 is set to 2 mm which is smaller than the removed width C of the MSQ film 32 by 3 mm.

Next, the unnecessary portions of the Cu film 36 and TaN film/Ta film 35 on the SiO₂ film 33 are removed by a CMP process using the above-described polishing conditions. Accordingly, a Cu wiring layer is formed as a third conductive layer.

As described above, in the substrates in which the edge removed widths A, B, C of the low-k dielectric films 12, 22, 32 of the respective conductive layers are broadened in stages, any steep stepped portion of the low-k dielectric films does not exist in the vicinity of the substrate edge 10. Therefore, a CMP pressure can be prevented from being locally applied to the edge of the low-k dielectric film of the lower in the Cu-CMP.

When the removed width of the upper low-k dielectric film is set to be larger than that of the lower low-k dielectric film by 0.4 mm or more, the low-k dielectric film can be prevented from being peeled in the Cu-CMP even in a sample having the lower low-k dielectric film whose Young's modulus is 4 GPa. When the removed width of the upper low-k dielectric film is set to be larger than that of the lower low-k dielectric film by 0.7 mm or more, the low-k dielectric film can be prevented from being peeled in the Cu-CMP even in a sample having the lower low-k dielectric film whose Young's modulus is 2 GPa. Furthermore, when the removed width of the upper low-k dielectric film is set to be larger than that of the lower low-k dielectric film by 1.0 mm or more, the low-k dielectric film can be prevented from being peeled in the Cu-CMP even in a sample having the lower low-k dielectric film whose Young's modulus is 1 GPa.

Moreover, the dielectric constant of the low-k dielectric film is changed, and the peeling of the low-k dielectric film is studied. As a result, when the substrate edge removed width of each-layer low-k dielectric film is set to be larger than that of the lower low-k dielectric film by 0.4 mm or more, the low-k dielectric film can be prevented from being peeled in the Cu-CMP even in a sample having the lower low-k dielectric film whose dielectric constant is 3.0. When the width is enlarged by 0.7 mm or more, the low-k dielectric film can be prevented from being peeled in the Cu-CMP even in a sample having the lower low-k dielectric film whose dielectric constant is 2.6. Furthermore, when the width is enlarged by 1.0 mm or more, the low-k dielectric film can be prevented from being peeled in the Cu-CMP even in a sample having the lower low-k dielectric film whose dielectric constant is 2.3. (Comparative Example)

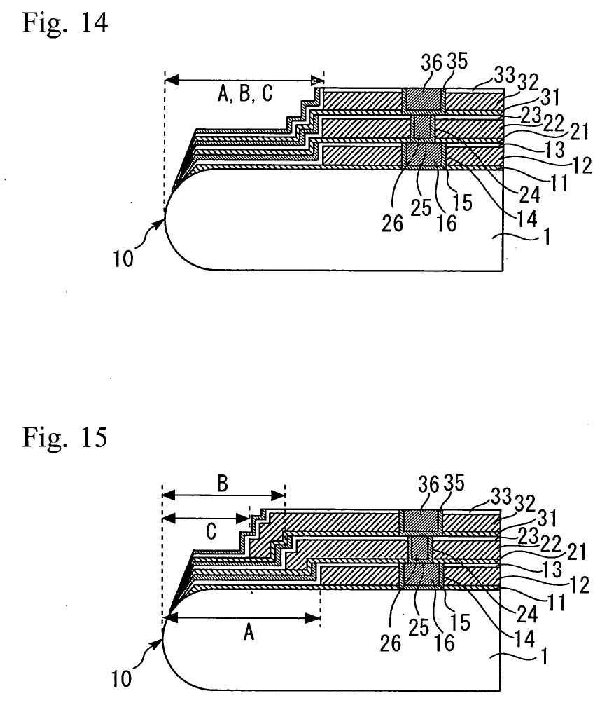

FIG. 14 is a sectional view showing a comparative example of Ninth Embodiment. As shown in FIG. 14, when substrate edge removed widths A, B, C of low-k dielectric films in layers are all set to 2 mm, and even when a Young's modulus of the low-k dielectric film is 12 GPa, a low-k dielectric film 12 peels in Cu-CMP of a first conductive layer. When each substrate edge removed width of the layer is set to 3 mm, and even when the Young's modulus of the low-k dielectric film is 12 GPa, the low-k dielectric film 12 peeled in the Cu-CMP of a second layer. When each substrate edge removed width of the layer is set to 4 mm, and even when the Young's modulus of the low-k dielectric film is 12 GPa, the low-k dielectric film 12 peels in the Cu-CMP of a third-level.

As described above, in Ninth Embodiment, a difference (edge removed width difference) between the removed width of the lower low-k dielectric film and that of the upper low-k dielectric film is set to 0.4 mm or more, and accordingly generation of the steep stepped portion of the low-k dielectric films in the substrate edge is avoided. Accordingly, a CMP pressure applied to the lower low-k dielectric film edge in the Cu-CMP of the upper can be largely reduced, and the lower low-k dielectric film in the Cu-CMP can be rapidly prevented from being peeled. When the edge removed width difference is increased to 0.7 mm or more, 1.0 mm or more, the stepped portion of the low-k dielectric film can further be eliminated. Even when a low-k dielectric film having a low Young's modulus or a low-k dielectric constant is used, the low-k dielectric film in the Cu-CMP can be prevented from being peeled.

In Ninth Embodiment, tilt of a stacked film can be moderated in the substrate edge as compared with Tenth Embodiment described later, and therefore the present embodiment is effective for the Cu-CMP of the upper wiring layer. That is, margins can be increased with respect to the peeling of a plurality of lower low-k dielectric films in the Cu-CMP of the upper wiring layer (this also applies to Twelfth and Fourteenth Embodiments described later).

It is to be noted that details will be described later. A similar result is obtained even when the present experiment is performed with respect to a wafer on which a device is mounted.

Moreover, in Ninth Embodiment, a single-damascene double-layer Cu wiring structure has been described, but the present invention is applicable to a dual-damascene double-layer Cu wiring structure, and an effect similar to that of Ninth Embodiment is obtained even in this case. The present invention is also applicable to a structure including three or more layers of Cu wirings, and the effect similar to that of Ninth Embodiment is obtained even in this case. In Ninth Embodiment, the low-k dielectric film applied in the single layer has been used, but a stacked film of the applied low-k dielectric film and a low-k dielectric film formed by the CVD method may be used as an interlayer film.

Tenth Embodiment

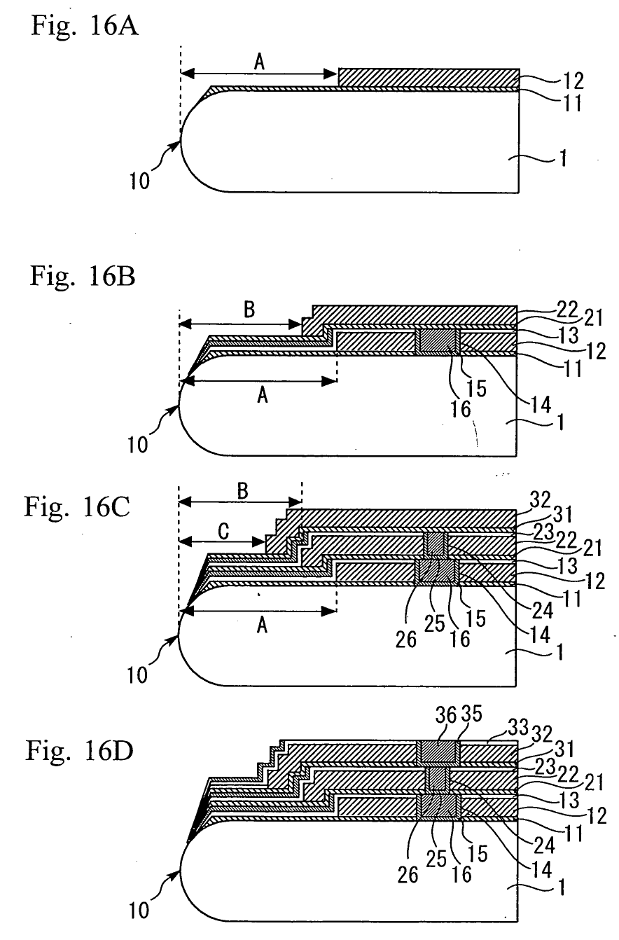

In Ninth Embodiment, the case where the removed width of the upper low-k dielectric film is set to be larger than that of the lower low-k dielectric film, that is, a case where the lower low-k dielectric film edge is on the side of a substrate outer periphery from the upper low-k dielectric film edge has been described. In Tenth Embodiment, a case where the removed width of the lower low-k dielectric film is set to be larger than that of the upper low-k dielectric film, that is, a case where the upper low-k dielectric film edge is on the side of the substrate outer periphery from the lower low-k dielectric film edge will be described. Since other respects are similar to those of Ninth Embodiment, different respects from Ninth Embodiment will be mainly described with reference to FIGS. 15 and 16A to 16D. FIG. 15 is a sectional view showing a multilayered wiring structure according to Tenth Embodiment. FIGS. 16A to 16D are process sectional view showing a method of forming a wiring according to Tenth Embodiment.

As shown in FIG. 15, a first low-k dielectric film 12 in the vicinity of a substrate edge 10 is removed by a removed width A (e.g., 5 mm), a second low-k dielectric film 22 is removed by a removed width B (e.g., 4 mm) which is smaller than the removed width A by 0.7 mm or more, and a third low-k dielectric film 32 is removed by a removed width C (e.g., 3 mm) which is smaller than the removed width B by 0.7 mm or more. Accordingly, a second low-k dielectric film 22 edge is positioned on the substrate outer peripheral side from a first low-k dielectric film 12 edge, and further a third low-k dielectric film 32 edge is positioned on the substrate outer peripheral side from the second low-k dielectric film 22 edge. Therefore, the first low-k dielectric film 12 edge is coated with the second low-k dielectric film 22, and the second low-k dielectric film 22 edge is coated with the third low-k dielectric film 32. Other respects are similar to those of Ninth Embodiment.

Next, a method of forming the multilayered wiring structure will be described.

First, as shown in FIG. 16A, a first diffusion barrier film 11 is formed on an underlayer 1, and is coated with a first low-k dielectric film 12. Immediately after the coating, the first low-k dielectric film 12 of a substrate outer peripheral portion is removed from a substrate edge 10 by a chemical solution by a width A. The removed width A is, for example, 5 mm. Thereafter, baking and curing are performed, and the surface of the first low-k dielectric film 12 is reformed with He-plasma.

Next, as shown in FIG. 16B, a first cap film 13 is formed on the first low-k dielectric film 12. Moreover, an opening 14 is formed in the first cap film 13, first low-k dielectric film 12, and first diffusion barrier film 11. Since the opening 14 is filled with a Cu film constituted of a barrier metal film 15 and a metal film 16, and a Cu wiring layer is formed as a first conductive layer. It is to be noted that a width of an edge of the Cu film 16, removed before the Cu-CMP, is 2 mm from the substrate edge 10 (this also applies to Cu films 26, 36 described later).

Next, a second diffusion barrier film 21 is formed on a first cap film 13 and the Cu wiring, and is coated with a second low-k dielectric film 22. Immediately after the coating, the second low-k dielectric film 22 of a substrate outer peripheral portion is removed by a chemical solution by a width B which is smaller than the width A of the first low-k dielectric film 12 by 0.7 mm or more. The removed width B is, for example, 4 mm. Accordingly, a second low-k dielectric film 22 edge is positioned on the substrate outer peripheral side from the first low-k dielectric film 12 edge by 0.7 mm or more.

Next, as shown in FIG. 16C, a second cap film 23 is formed on the second low-k dielectric film 22. Moreover, a via hole serving as an opening 24 is formed in the second cap film 23, second low-k dielectric film 22, and second diffusion barrier film 21. Since the opening 24 is filled with a barrier metal film 25 and a metal film 26, a via layer is formed as a second conductive layer.

Next, a third diffusion barrier film 31 is formed on the second cap film 23 and the via layer, and is coated with a third low-k dielectric film 32. Immediately after the coating, the third low-k dielectric film 32 of a substrate outer peripheral portion is removed by a chemical solution by a width C which is smaller than the removed width B of the second low-k dielectric film 22 by 0.7 mm or more. The removed width C is, for example, 3 mm. Accordingly, a third low-k dielectric film 32 edge is positioned on the substrate outer peripheral side from the second low-k dielectric film 22 edge by 0.7 mm or more and from the low-k dielectric film 12 edge by 1.4 mm or more.

Next, as shown in FIG. 16D, a third cap film 33 is formed on the third low-k dielectric film 32. Moreover, an opening 34 is formed in the third cap film 33, third low-k dielectric film 32, and third diffusion barrier film 31. Since the opening 34 is filled with a barrier metal film 35 and a metal film 36, a Cu wiring layer is formed as a third conductive layer.

Also in Tenth Embodiment, in the same manner as in Ninth Embodiment, a difference between the removed width of the lower low-k dielectric film and that of the upper low-k dielectric film is set to 0.7 mm or more, and accordingly generation of the steep stepped portion of the low-k dielectric films in the substrate edge is avoided. Accordingly, a CMP pressure applied to the lower low-k dielectric film edge in the Cu-CMP of the upper can be largely reduced, and the lower low-k dielectric film in the Cu-CMP can be rapidly prevented from being peeled. When the edge removed width difference is increased to 1.0 mm or more, the stepped portion of the low-k dielectric film can further be eliminated. Even when a low-k dielectric film having a low Young's modulus or a low-k dielectric constant is used, the low-k dielectric film in the Cu-CMP can be prevented from being peeled.

Moreover, in Tenth Embodiment, the upper low-k dielectric film edge is positioned outside the lower low-k dielectric film edge at a time when the Cu film is removed with a chemical solution (immediately before the Cu-CMP). That is, the lower low-k dielectric film edge is coated with the upper low-k dielectric film in the Cu-CMP. Therefore, the lower low-k dielectric film can further be prevented from being peeled in the Cu-CMP by an anchor effect as compared with First Embodiment.

Eleventh Embodiment

Eleventh Embodiment is characterized in that an edge removed width of a low-k dielectric film of an odd-numbered wiring layer is set to be different from that of the low-k dielectric film of an even-numbered wiring layer.

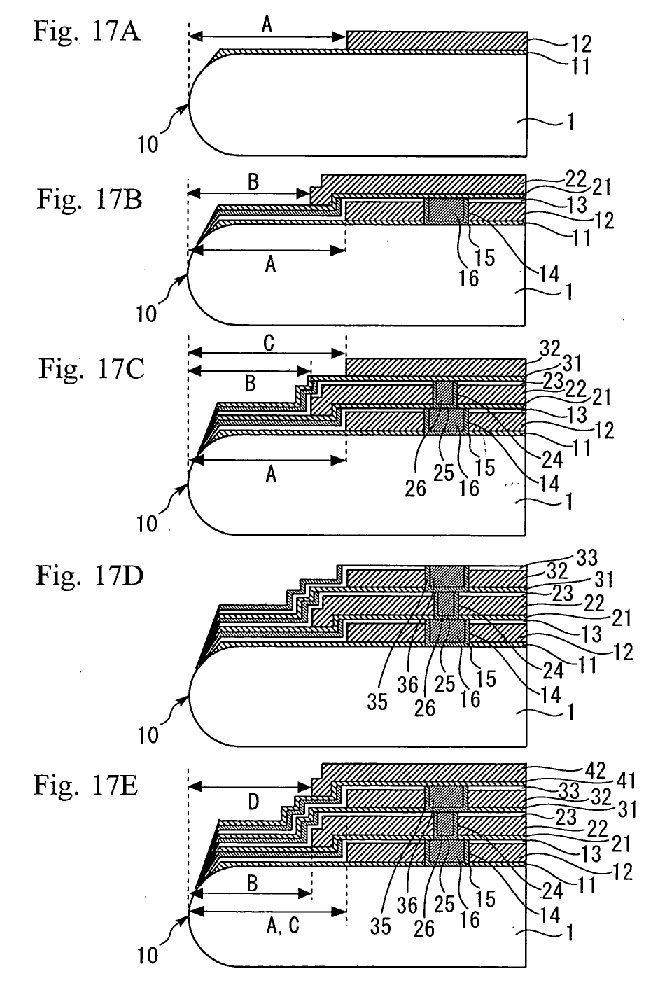

FIGS. 17A to 17E are process sectional views showing a method of forming a wiring according to Eleventh Embodiment of the present invention.

First, as shown in FIGS. 17A and 17B, an edge of a second low-k dielectric film 22 is removed using a method similar to that of Tenth Embodiment. That is, a removed width B of the second low-k dielectric film 22 of a substrate outer peripheral portion is set to be smaller than a removed width A of a first low-k dielectric film 12. For example, the removed width A is 2 mm, and the removed width B is 1 mm.

Next, as shown in FIG. 17C, a third low-k dielectric film 32 is formed using the method similar to that of Tenth Embodiment. Thereafter, the third low-k dielectric film 32 of the substrate outer peripheral portion is removed by a width C which is equal to the removed width A of the first low-k dielectric film 12.

Next, steps until polishing of a Cu film 36 are performed using the method similar to that of Tenth Embodiment, and accordingly a structure shown in FIG. 17D is obtained.

Thereafter, as shown in FIG. 17E, a fourth diffusion barrier film 41 is formed on a third wiring layer, and is coated with a fourth low-k dielectric film 42. After the coating, the fourth low-k dielectric film 42 of the substrate outer peripheral portion is removed by a width D which is equal to the removed width B of the second low-k dielectric film 22. Thereafter, although not shown, a fourth cap film is formed, an opening is formed, a barrier metal film and a Cu film are deposited, and a Cu film is successively polished. Accordingly, a via layer is formed as a fourth conductive layer. A difference between the removed width A, C and the removed width B, D is preferably 0.4 mm or more, more preferable 0.7 mm or more.

As described above, in Eleventh Embodiment, the edge removed widths A, C of the low-k dielectric films 12, 32 of the odd-numbered wiring layer are differentiated from edge removed widths B, D of the low-k dielectric films 22, 42 of the even-numbered wiring layer. Accordingly, a CMP pressure applied to the lower low-k dielectric film edge can be largely reduced-in the Cu-CMP of the upper, and therefore the lower low-k dielectric film can be rapidly prevented from being peeled in the Cu-CMP.

Moreover, in Eleventh Embodiment, the edge removed width is not larger than B, and therefore a chip acquisition ratio can be enhanced as compared with Ninth and Tenth Embodiments.

Twelfth Embodiment

In Twelfth Embodiment of the present invention, a multilayered wiring structure of Ninth Embodiment described above is applied to wirings of a first and subsequent layers in a semiconductor device.

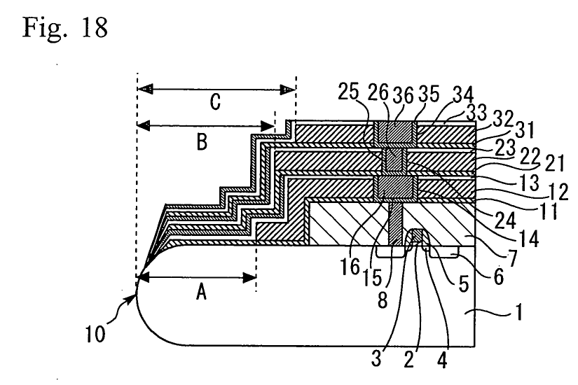

FIG. 18 is a sectional view showing a semiconductor device according to Twelfth Embodiment of the present invention.

As shown in FIG. 18, a semiconductor element having a diffusion layer 6, such as a MIS transistor, is formed on a substrate 1. Concretely, a gate electrode 3 is formed on a silicon substrate serving as the substrate 1 via a gate insulating film 2. Sidewalls 5 for forming a LDD structure are formed on opposite sides of the gate electrode 3. A low-concentration diffusion layer (extension region) 4 is formed in an upper of the substrate 1 via a channel region (not shown) right under the gate insulating film 2, and a high-concentration diffusion layer (source/drain region) 6 to be connected to the low-concentration diffusion layer 4 is formed.

An interlayer insulating film 7 is formed in so as to cover the semiconductor element, and a contact 8 to be connected to the diffusion layer 6 is formed in the interlayer insulating film 7.

The multilayered wiring structure of Ninth Embodiment is applied to wiring on the contact 8 and the interlayer insulating film 7.

Concretely, a first diffusion barrier film 11 is formed on the contact 8 and the interlayer insulating film 7, and a first low-k dielectric film 12 is formed on the diffusion barrier film and removed from a substrate edge 10 by a width A.

A first cap film 13 for preventing plasma damages is formed on the first low-k dielectric film 12.

An opening 14 reaching the upper surface of the contact 8 is formed in the first cap film 13, the first low-k dielectric film 12, and the first diffusion barrier film 11, and a barrier metal film 15 is formed on the inner wall of the opening 14. Furthermore, a metal film 16 is formed on the barrier metal film 15. That is, since the opening 14 is filled with a conductive film constituted of the barrier metal film 15 and the metal film 16, a first conductive layer contacting the diffusion layer 6 via the contact 8 is formed in the opening 14. The opening 14 is a wiring groove, a via hole or the like (this also applies to openings 24, 34 described later).

A second diffusion barrier film 21 is formed on the first conductive layer and the first cap film 13, a second low-k dielectric film 22 is formed on the diffusion barrier film, and further a second cap film 23 is formed on the low-k dielectric film. Here, the second low-k dielectric film 22 is removed from the substrate edge 10 by a width B larger than a removed width A of the first low-k dielectric film 12 by 0.4 mm or more. That is, the edge removed width B of the second low-k dielectric film 22 is larger than the edge removed width A of the first low-k dielectric film 12 by 0.4 mm or more. Accordingly, a second low-k dielectric film 22 edge is distant from a first low-k dielectric film 12 edge, and a CMP pressure can be prevented from being excessively concentrated on the first low-k dielectric film 12 edge during CMP of a metal film 26 described later. Details will be described later. A difference (hereinafter referred to as the “edge removed width difference”) between the removed width B and the removed width A is set to 0.7 mm or more, 1.0 mm or more. The difference set to be large in this manner is effective in preventing the low-k dielectric film from being peeled in the Cu-CMP.

Moreover, it is optimum to change the edge removed width difference in accordance with the film thickness of the low-k dielectric film in the same manner as in Ninth Embodiment.

Assuming that a low-k dielectric film having a Young's modulus of 2 GPa or more and less than 4 GPa is used, when the film thickness of the low-k dielectric film is 10 nm or more and less than 500 nm, an edge removed width difference is preferably set to 0.7 mm or more. When the film thickness is 500 nm or more and less than 800 nm, the edge removed width difference is preferably set to 0.8 mm or more. When the film thickness is 800 nm or more and less than 2000 nm, the edge removed width difference is preferably set to 1.2 mm or more. When the film thickness is 2000 nm or more, the edge removed width difference is preferably set to 1.5 mm or more.

Assuming that a low-k dielectric film having a Young's modulus of 4 GPa or more is used, when the film thickness of the low-k dielectric film is less than 300 nm, the edge removed width difference is preferably set to 0.4 mm or more. When the film thickness is 300 nm or more and less than 600 nm, the edge removed width difference is preferably set to 0.7 mm or more. When the film thickness is 600 nm or more, the edge removed width difference is preferably set to 1.0 mm or more.

Moreover, an opening 24 reaching the surface of the Cu film 15 is formed in the second cap film 23, the second low-k dielectric film 22, and the second diffusion barrier film 21, and a barrier metal film 25 is formed on the inner wall of the opening 24. Furthermore, a metal film 26 is formed on the barrier metal film 25. That is, since the opening 24 is filled with a conductive film constituted of the barrier metal film 25 and the metal film 26, a second conductive layer is formed in the opening 24. Therefore, the second conductive layer is connected to the first conductive layer.

A third diffusion barrier film 31 is formed on the second conductive layer and the second cap film 23, a third low-k dielectric film 32 is formed on the third diffusion barrier film 31, and further a third cap film 33 is formed on the third low-k dielectric film 32. Here, the third low-k dielectric film 32 is removed from the substrate edge 10 by a width C larger than a removed width B of the second low-k dielectric film 22 by 0.4 mm or more. That is, the edge removed width C of the third low-k dielectric film 32 is larger than the edge removed width B of the second low-k dielectric film 22 by 0.4 mm or more. Accordingly, a third low-k dielectric film 32 edge is distant from a second low-k dielectric film 22 edge and first low-k dielectric film 12 edge, and a CMP pressure can be prevented from being excessively concentrated on the second low-k dielectric film 22 edge and first low-k dielectric film 12 edge during CMP of a metal film 36 described later.

Moreover, an opening 34 reaching the metal film 26 is formed in the third cap film 33, the third low-k dielectric film 32, and the third diffusion barrier film 31. A barrier metal film 35 is formed on the inner wall of the opening 34. Furthermore, the metal film 36 is formed on the barrier metal film 35. That is, since the opening 34 is filled with a conductive film constituted of the barrier metal film 35 and the metal film 36, a third conductive layer is formed in the opening 34. Therefore, the third conductive layer is connected to the second conductive layer.

Next, a method of manufacturing the semiconductor device will be described.

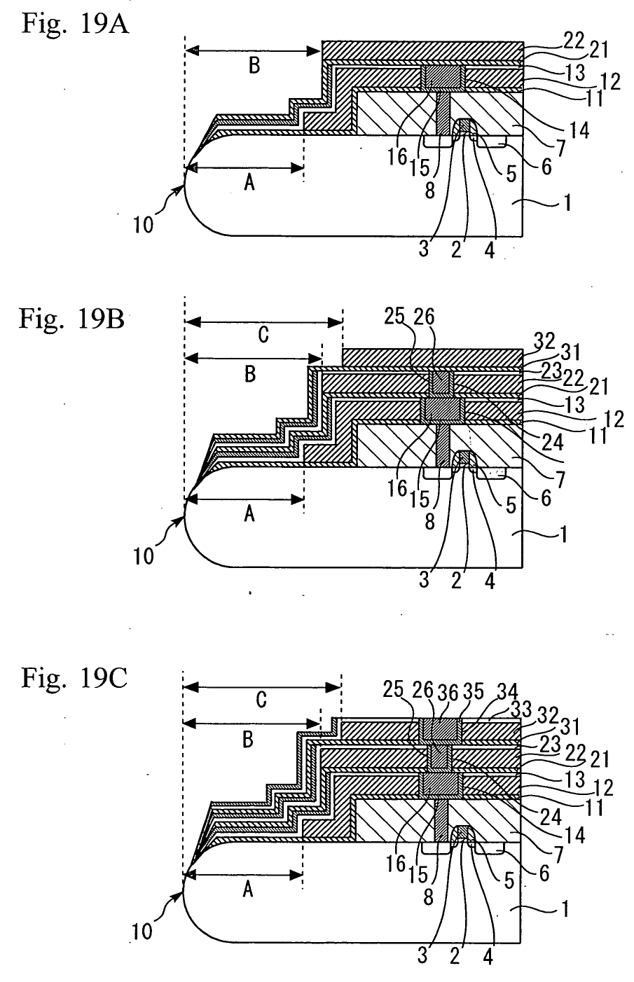

FIGS. 19A to 19C are process sectional views showing a method of manufacturing a semiconductor device according to Twelfth Embodiment of the present invention.

First, as shown in FIG. 19A, a semiconductor element having a diffusion layer, such as a MIS transistor, is formed on a substrate 1. Although detailed description is omitted, a gate insulating film 2 and a conductive film 3 are formed on a silicon substrate serving as the substrate 1, and thereafter these films 3, 2 are successively patterned to form a gate electrode 3. Impurities are implanted into the substrate 1 using the gate electrode 3 as a mask to thereby form a low-concentration diffusion layers (extension regions) 4, and side walls 5 are formed on opposite sides of the gate electrode 3. The impurities are implanted into the substrate 1 using the side walls 5 and the gate electrode 3 as masks to thereby form a high-concentration diffusion layers (source/drain regions) 6.

Moreover, a SiO₂ film is formed as an insulating film 7, for example, in a film thickness of 500 nm in such a manner as to coat the transistor formed by performing the above-described steps, and a contact 8 to be connected to the high-concentration conductive layer 6 is formed in the interlayer insulating film 7.

Next, a first diffusion barrier film 11 is formed, for example, in a film thickness of 30 nm to 200 nm on the interlayer insulating film 7 and the contact 8 by a CVD method. Moreover, immediately after a MSQ film is formed as a low-k dielectric film 12, for example, in a film thickness of 100 nm to 1000 mm on the first diffusion barrier film 11 by a spin coating method, the first low-k dielectric film 12 of a substrate outer peripheral portion is removed by a chemical solution by a width A. That is, the first low-k dielectric film 12 is removed from a substrate edge 10 by the removed width A. Thereafter, baking and curing are performed in an inactive gas atmosphere, and further He plasma is applied to thereby reform the surface of the first low-k dielectric film 12.

Next, a first cap film 13 is formed, for example, in a film thickness of 30 nm to 200 nm on the first low-k dielectric film 12 by the CVD method. Moreover, an opening 14 reaching the upper surface of the contact 8 is formed in the first cap film 13, first low-k dielectric film 12, and first diffusion barrier film 11 by a lithography technique and dry etching. Moreover, a barrier metal film 15 is formed on inner walls of the opening 14 and the first cap film 13 by a sputtering method, and a seed Cu film is formed on the barrier metal film 15 by the sputtering method. Furthermore, a Cu film 16 is formed on the seed Cu film by an electrolytic plating method. Thereafter, annealing is performed. It is to be noted that the annealing may be performed after removing the Cu film 16 with a chemical solution.

Next, the Cu film 16 of the substrate outer peripheral portion is removed by the chemical solution. A removed width of the Cu film 16, that is, a length from the substrate edge 10 to the Cu film edge is set to 3 mm.

Thereafter, unnecessary portions of the Cu film 16 and barrier metal film 15 formed on the first cap film 13 are removed using an orbital-type CMP apparatus in the same manner as in Ninth Embodiment. A Cu wiring layer of a first conductive layer to be electrically connected to the diffusion layer 6 via the contact 8 is formed through the above-described steps.

Next, a second diffusion barrier film 21 is formed, for example, in a film thickness of 30 nm to 200 nm on the first cap film 13 and Cu wiring by the CVD method. Next, immediately after a second low-k dielectric film 22 is formed, for example, in a film thickness of 100 nm to 1000 nm on the second diffusion barrier film 21 by the spin coating method, the second low-k dielectric film 22 of a substrate outer peripheral portion is removed by a chemical solution by a width B. The removed width B of the second low-k dielectric film 22 is set to, for example, 4 mm which is larger than the removed width A of the first low-k dielectric film 12 by 1 mm. Thereafter, the baking and curing are performed in the inactive gas atmosphere, and further the surface of the second low-k dielectric film 22 is reformed by irradiation with He plasma.

Next, as shown in FIG. 19B, a second cap film 23 is formed, for example, in a film thickness of 30 nm to 200 nm on the second low-k dielectric film 22 by the CVD method. Moreover, an opening 24 is formed in the second cap film 23, second low-k dielectric film 22, and second diffusion barrier film 21 by the lithography technique and dry etching. Next, a barrier metal film 25 is formed on an inner wall of the opening 24 and the second cap film 23 by the sputtering method, and a seed Cu film is formed on the barrier metal film 25 by the sputtering method. Furthermore, a Cu film 26 is formed on the seed Cu film by the electrolytic plating method. Thereafter, the annealing is performed. Accordingly, the opening 24 is filled with a conductive film constituted of the barrier metal film 25, the seed Cu film, and the Cu film 26.

Next, the Cu film 26 of the substrate outer peripheral portion is removed by the chemical solution. A removed width of the Cu film 26 is set, for example, to 2 mm which is smaller than the removed width B of the second low-k dielectric film 22 by 2 mm. Thereafter, the CMP is performed on conditions similar to those of the Cu wiring layer of the first conductive layer, and accordingly the unnecessary portions of the Cu film 26 and barrier metal film 25 formed on the second cap film 23 are removed. Accordingly, a via layer is formed as a second conductive layer.

Next, a third diffusion barrier film 31 is formed, for example, in a film thickness of 30 nm to 200 nm on the second cap film 23 and the via layer by the CVD method. Moreover, immediately after a third low-k dielectric film 32 is formed, for example, in a film thickness of 100 nm to 1000 nm on the third diffusion barrier film 31 by the spin coating method, the third low-k dielectric film 32 of a substrate outer peripheral portion is removed by a chemical solution by a width C. The removed width C of the third low-k dielectric film 32 is, for example, 5 mm which is larger than the removed width B of the second low-k dielectric film 22 by 1 mm. Thereafter, the baking and curing are performed in the inactive gas atmosphere, and further the surface of the third low-k dielectric film 32 is reformed by irradiation with He plasma.

Next, as shown in FIG. 19C, a third cap film 33 is formed, for example, in a film thickness of 30 nm to 200 nm on the third low-k dielectric film 32 by the CVD method. Moreover, an opening 34 is formed in the third cap film 33, third low-k dielectric film 32, and third diffusion barrier film 31 by the lithography technique and dry etching. Next, a barrier metal film 35 is formed on an inner wall of the opening 34 and the third cap film 33 by the sputtering method, and a seed Cu film is formed on the barrier metal film 35 by the sputtering method. Furthermore, a Cu film 36 is formed on the seed Cu film by the electrolytic plating method. Thereafter, the annealing is performed. Accordingly, the opening 34 is filled with a conductive film constituted of the barrier metal film 35, the seed Cu film, and the Cu film 36.

Next, the Cu film 36 of the substrate outer peripheral portion is removed by the chemical solution. A removed width of the Cu film 36 is set, for example, to 2 mm which is smaller than the removed width C of the third low-k dielectric film 32 by 3 mm. Thereafter, the CMP is performed on conditions similar to those of the Cu wiring layer of the first layer, and accordingly unnecessary portions of the Cu film 36 and barrier metal film 35 formed on the second cap film 33 are removed. Accordingly, a Cu wiring layer is formed as a third conductive layer.

As described above, in Twelfth Embodiment, a difference between the edge removed width of the upper low-k dielectric film and that of the lower low-k dielectric film is set to 0.4 mm or more, and accordingly generation of the steep stepped portion of the low-k dielectric films in the substrate edge is avoided. Accordingly, a CMP pressure applied to the lower low-k dielectric film edge in the Cu-CMP of the upper can be largely reduced, and the lower low-k dielectric film in the Cu-CMP can be rapidly prevented from being peeled. When the edge removed width difference is increased to 0.7 mm or more, 1.0 mm or more, the stepped portion of the low-k dielectric film can further be eliminated. Even when a low-k dielectric film having a low Young's modulus or a low-k dielectric constant is used, the low-k dielectric film in the Cu-CMP can be prevented from being peeled.

Therefore, yield can be enhanced, and reliability of the semiconductor device can be improved. A Cu damascene wiring using the low-k dielectric film is applicable to the wiring of the semiconductor device, and performance of the semiconductor device can be enhanced.

Thirteenth Embodiment

In Thirteenth Embodiment of the present invention, a multilayered wiring structure of Tenth Embodiment described above is applied to wirings of a first and subsequent layers in a semiconductor device.

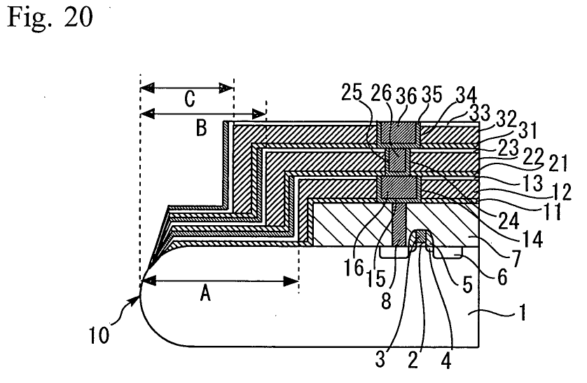

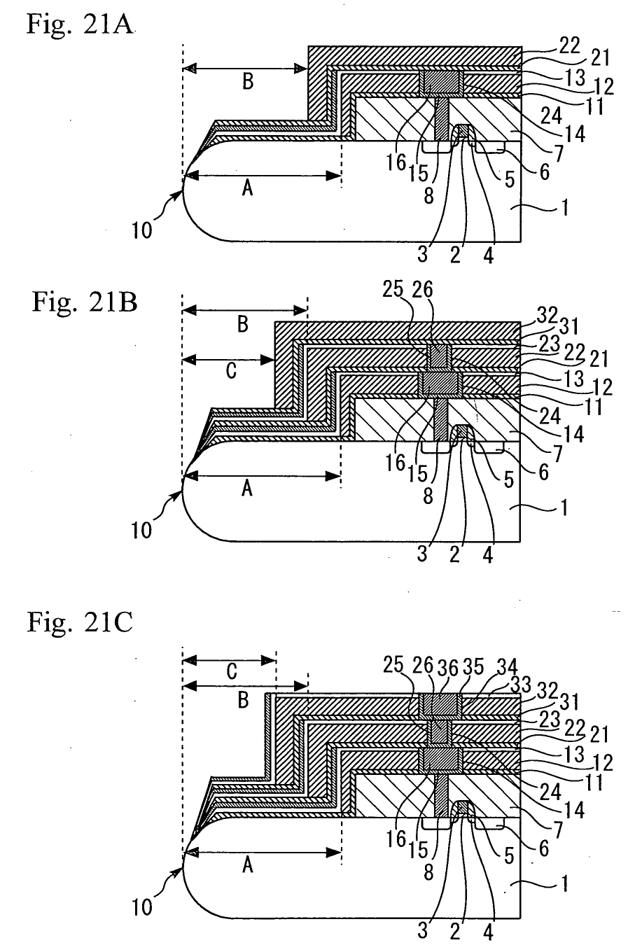

In Twelfth Embodiment, the case where the removed width of the upper low-k dielectric film is set to be larger than that of the lower low-k dielectric film, that is, a case where the lower low-k dielectric film edge is on the side of a substrate outer periphery from the upper low-k dielectric film edge has been described. In Thirteenth Embodiment, a case where the removed width of the lower low-k dielectric film is set to be larger than that of the upper low-k dielectric film, that is, a case where the upper low-k dielectric film edge is on the side of the substrate outer periphery from the lower low-k dielectric film edge will be described. Since other respects are similar to those of Twelfth Embodiment, different respects from Twelfth Embodiment will be mainly described with reference to FIGS. 20 and 21A to 21C. FIG. 20 is a sectional view showing a semiconductor device according to Thirteenth Embodiment. FIGS. 21A to 21C are process sectional views showing a method of manufacturing a semiconductor device according to Thirteenth Embodiment.

As shown in FIG. 20, a MIS transistor is formed as a semiconductor element having a diffusion layer on a substrate 1. Furthermore, an interlayer insulating film 7 is formed in so as to cover the transistor, and a contact 8 connecting to a diffusion layer 6 is formed in the interlayer insulating film 7.

The multilayered wiring structure of Second Embodiment is applied to wirings on the contact 8 and the interlayer insulating film 7. Concretely, three layers of low-k dielectric films 12, 22, 32 are stacked, and a conductive layer is formed in each low-k dielectric film.

As shown in FIG. 20, a first low-k dielectric film 12 in the vicinity of a substrate edge 10 is removed by a removed width A, a second low-k dielectric film 22 is removed by a removed width B which is smaller than the removed width A by 0.7 mm or more, and a third low-k dielectric film 32 is removed by a removed width C which is smaller than the removed width B by 0.7 mm or more. Accordingly, a second low-k dielectric film 22 edge is positioned on the substrate outer peripheral side from a first low-k dielectric film 12 edge, and further a third low-k dielectric film 32 edge is positioned on the substrate outer peripheral side from the second low-k dielectric film 22 edge. Therefore, the first low-k dielectric film 12 edge is coated with the second low-k dielectric film 22, and the second low-k dielectric film 22 edge is coated with the third low-k dielectric film 32. Other respects are similar to those of Third Embodiment.

Next, a method of manufacturing the semiconductor device will be described.

First, as shown in FIG. 21A, a MIS transistor is formed on a substrate 1 using the method described in Twelfth Embodiment. An interlayer insulating film 7 is formed in so as to cover the transistor, and a contact 8 connecting to the diffusion layer 6 is formed in the interlayer insulating film 7.

Next, a first diffusion barrier film 11 is formed on the contact 8 and the interlayer insulating film 7, and is coated with a first low-k dielectric film 12. Immediately after the coating, the first low-k dielectric film 12 of a substrate outer peripheral portion is removed from a substrate edge 10 by a chemical solution by a width A. Thereafter, baking and curing are performed, and further the surface of the first low-k dielectric film 12 is reformed by He plasma.

Next, a first cap film 13 is formed on the first low-k dielectric film 12. Moreover, an opening 14 reaching the upper surface of the contact 8 is formed in the first cap film 13, first low-k dielectric film 12, and first diffusion barrier film 11. Thereafter, the opening 14 is filled with a barrier metal film 15 and a metal film 16 which are Cu films using a method similar to that of Third Embodiment, and accordingly a Cu wiring layer is formed as a first conductive layer.

Next, a second diffusion barrier film 21 is formed on the first cap film 13 and Cu wiring, and coated with a second low-k dielectric film 22. Immediately after the coating, the second low-k dielectric film 22 of a substrate outer peripheral portion is removed by a chemical solution by a width B which is smaller than the width A of the first low-k dielectric film 12 by 0.7 mm or more. Accordingly, a second low-k dielectric film 22 edge is positioned on the substrate outer peripheral side from the first low-k dielectric film 12 edge by 0.7 mm or more.

Next, as shown in FIG. 21B, a second cap film 23 is formed on the second low-k dielectric film 22. Moreover, a via hole serving as an opening 24 is formed in the second cap film 23, second low-k dielectric film 22, and second diffusion barrier film 21. Thereafter, the opening 24 is filled with a barrier metal film 25 and a metal film 26 using a method similar to that of Twelfth Embodiment, and accordingly a via layer is formed as a second conductive layer.

Next, a third diffusion barrier film 31 is formed on the second cap film 23 and the via layer, and is coated with a third low-k dielectric film 32. Immediately after the coating, the third low-k dielectric film 32 of a substrate outer peripheral portion is removed by a chemical solution by a width C which is smaller than the removed width B of the second low-k dielectric film 22 by 0.7 mm or more. Accordingly, a third low-k dielectric film 32 edge is positioned on the substrate outer peripheral side from the second low-k dielectric film 22 edge by 0.7 mm or more and from the low-k dielectric film 12 edge by 1.4 mm or more.

Next, as shown in FIG. 21C, a third cap film 33 is formed on the third low-k dielectric film 32. Moreover, an opening 34 is formed in the third cap film 33, third low-k dielectric film 32, and third diffusion barrier film 31. The opening 34 is filled with a barrier metal film 35 and a metal film 36 which are Cu films using a method similar to that of Twelfth Embodiment, and accordingly a Cu wiring layer is formed as a third conductive layer.

Also in Thirteenth Embodiment, in the same manner as in Tenth Embodiment, a difference between the edge removed width of the upper low-k dielectric film and that of the lower low-k dielectric film is set to 0.7 mm or more, and accordingly generation of the steep stepped portion of the low-k dielectric films in the substrate edge is avoided. Accordingly, a CMP pressure applied to the lower low-k dielectric film edge in the Cu-CMP of the upper can be largely reduced, and the lower low-k dielectric film in the Cu-CMP can be rapidly prevented from being peeled. When the edge removed width difference is increased to 1.0 mm or more, the stepped portion of the low-k dielectric film can further be eliminated. Even when a low-k dielectric film having a low Young's modulus or a low-k dielectric constant is used, the low-k dielectric film in the Cu-CMP can be prevented from being peeled.

Moreover, in Thirteenth Embodiment, the upper low-k dielectric film edge is positioned outside the lower low-k dielectric film edge at a time when the Cu film is removed with a chemical solution (immediately before the Cu-CMP). That is, the lower low-k dielectric film edge is coated with the upper low-k dielectric film in the Cu-CMP. Therefore, the lower low-k dielectric film can further be prevented from being peeled in the Cu-CMP by an anchor effect as compared with Twelfth Embodiment.

Therefore, yield can be enhanced, and reliability of the semiconductor device can be improved. A Cu damascene wiring using the low-k dielectric film is applicable to the wiring of the semiconductor device, and performance of the semiconductor device can be enhanced.

Fourteenth Embodiment

In Fourteenth Embodiment of the present invention, the above-described multilayered wiring structure of Ninth Embodiment is applied to a wiring of a semiconductor mounted device. Concretely, the embodiment is applied to the wiring on the semiconductor chip, when packaging a semiconductor chip into a module.

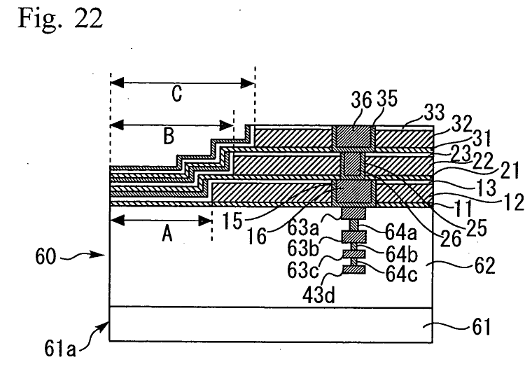

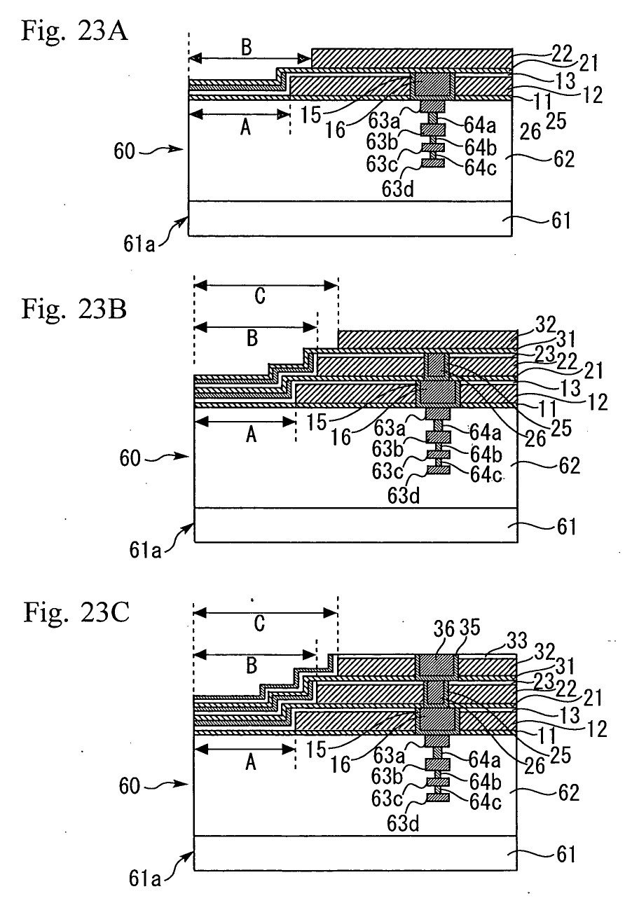

FIG. 22 is a sectional view showing a semiconductor mounted device according to Fourteenth Embodiment. FIGS. 23A to 23C are process sectional views showing a method of manufacturing a semiconductor mounted device according to Fourteenth Embodiment.

As shown in FIG. 22, a semiconductor chip (semiconductor device) 60 is formed comprising a semiconductor element (not shown), and a multilayered wiring structure 62 having multilevel wiring layers 63a, 63b, 63c, 63d formed on the semiconductor element and via-contacts 64a, 64b, 64c which connect the layers to one another in an insulating film on a substrate 61. It is to be noted that the semiconductor element has been described in Twelfth Embodiment.

A first diffusion barrier film 11 is formed on the wiring layer 63a of the multilayered wiring structure 42, and a first low-k dielectric film 12 removed from a substrate edge 10 by a width A is formed on the first diffusion barrier film 11.

A first cap film 13 for preventing plasma damages is formed on the first low-k dielectric film 12.

An opening 14 reaching the upper surface of the wiring layer 63a is formed in the first cap film 13, the first low-k dielectric film 12, and the first diffusion barrier film 11, and a barrier metal film 15 is formed on the inner wall of the opening 14. Furthermore, a metal film 16 is formed on the barrier metal film 15. That is, since the opening 14 is filled with a conductive film constituted of the barrier metal film 15 and the metal film 16, a first conductive layer contacting the diffusion layer 6 via the wiring layers 63a, 63b, 63c, 63d, via-contacts 64a, 64b, 64c, and contact 8 is formed in the opening 14. The opening 14 is a wiring groove, a via hole or the like (this also applies to openings 24, 34 described later).

A second diffusion barrier film 21 is formed on the first conductive layer and the first cap film 13. A second low-k dielectric film 22 is formed on the second diffusion barrier film 21, and further a second cap film 23 is formed on the second low-k dielectric film 22. Here, the second low-k dielectric film 22 is removed from the substrate edge 10 by a width B larger than a removed width A of the first low-k dielectric film 12 by 0.4 mm or more. That is, the edge removed width B of the second low-k dielectric film 22 is larger than the edge removed width A of the first low-k dielectric film 12 by 0.4 mm or more. Accordingly, a second low-k dielectric film 22 edge is distant from a first low-k dielectric film 12 edge, and a CMP pressure can be prevented from being excessively concentrated on the first low-k dielectric film 12 edge during CMP of a metal film 26 described later. Details will be described later. A difference (hereinafter referred to as the “edge removed width difference”) between the removed width B and the removed width A is set to 0.7 mm or more, 1.0 mm or more. The difference set to be large in this manner is effective in preventing the low-k dielectric film from being peeled in the Cu-CMP.

Moreover, it is optimum to change the edge removed width difference in accordance with the film thickness of the low-k dielectric film in the same manner as in Ninth and Twelfth Embodiments. Assuming that a low-k dielectric film having a Young's modulus of 2 GPa or more and less than 4 GPa is used, when the film thickness of the low-k dielectric film is 10 nm or more and less than 500 nm, an edge removed width difference is preferably set to 0.7 mm or more. When the film thickness is 500 nm or more and less than 800 nm, the edge removed width difference is preferably set to 0.8 mm or more. When the film thickness is 800 nm or more and less than 2000 nm, the edge removed width difference is preferably set to 1.2 mm or more. When the film thickness is 2000 nm or more, the edge removed width difference is preferably set to 1.5 mm or more. Assuming that a low-k dielectric film having a Young's modulus of 4 GPa or more is used, when the film thickness of the low-k dielectric film is less than 300 nm, the edge removed width difference is preferably set to 0.4 mm or more. When the film thickness is 300 nm or more and less than 600 nm, the edge removed width difference is preferably set to 0.7 mm or more. When the film thickness is 600 nm or more, the edge removed width difference is preferably set to 1.0 mm or more.

Moreover, an opening 24 reaching the surface of the Cu film 15 is formed in the second cap film 23, the second low-k dielectric film 22, and the second diffusion barrier film 21. A barrier metal film 25 is formed on the inner wall of the opening 24. Furthermore, a metal film 26 is formed on the barrier metal film 25. That is, since the opening 24 is filled with a conductive film constituted of the barrier metal film 25 and the metal film 26, a second conductive layer is formed in the opening 24. Therefore, the second conductive layer is connected to the first conductive layer.

A third diffusion barrier film 31 is formed on the second conductive layer and the second cap film 23, a third low-k dielectric film 32 is formed on the third diffusion barrier film 31, and further a third cap film 33 is formed on the third low-k dielectric film 32. Here, the third low-k dielectric film 32 is removed from the substrate edge 10 by a width C larger than a removed width B of the second low-k dielectric film 22 by 0.4 mm or more. That is, the edge removed width C of the third low-k dielectric film 32 is larger than the edge removed width B of the second low-k dielectric film 22 by 0.4 mm or more. Accordingly, a third low-k dielectric film 32 edge is distant from a second low-k dielectric film 22 edge and first low-k dielectric film 12 edge, and a CMP pressure can be prevented from being excessively concentrated on the second low-k dielectric film 22 edge and first low-k dielectric film 12 edge during CMP of a metal film 36 described later.

Moreover, an opening 34 reaching the metal film 26 is formed in the third cap film 33, the third low-k dielectric film 32, and the third diffusion barrier film 31. A barrier metal film 35 is formed on the inner wall of the opening 34. Furthermore, the metal film 36 is formed on the barrier metal film 35. That is, since the opening 34 is filled with a conductive film constituted of the barrier metal film 35 and the metal film 36, a third conductive layer is formed in the opening 34. Therefore, the third conductive layer is connected to the second conductive layer.

Next, a method of manufacturing the semiconductor mounted device will be described.

First, as shown in FIG. 23A, a semiconductor chip (semiconductor device) 60 is formed comprising a multilayered wiring structure 62 having multilevel wiring layers 63a, 63b, 63c, 63d and via-contacts 64a, 64b, 64c which connect the layers to one another in an insulating film on a substrate 61. It is to be noted that a semiconductor element (e.g., MIS transistor) in the multi layered wiring structure 62 has been described in Twelfth Embodiment, and therefore drawing and description are omitted.

Next, a first diffusion barrier film 11 is formed, for example, in a film thickness of 30 nm to 200 nm on the multilayered wiring structure 62 by a CVD method. Moreover, immediately after a MSQ film is formed as a first low-k dielectric film 12, for example, in a film thickness of 100 nm to 1000 mm on the diffusion barrier film 11 by a spin coating method, the first low-k dielectric film 12 of a substrate outer peripheral portion is removed by a width A by a chemical solution. That is, the first low-k dielectric film 12 is removed from a substrate edge 10 by the removed width A. Thereafter, baking and curing are performed in an inactive gas atmosphere, and further the surface of the first low-k dielectric film 12 is reformed by irradiation with He plasma.

Next, a first cap film 13 is formed, for example, in a film thickness of 30 nm to 200 nm on the first low-k dielectric film 12 by a CVD method. Moreover, an opening 14 reaching the upper surface of the wiring layer 63a is formed in the first cap film 13, the first low-k dielectric film 12, and the first diffusion barrier film 11 by a lithography technique and dry etching. Moreover, a barrier metal film 15 is formed on the inner wall of the opening 14 and the first cap film 13 by a sputtering method, and a seed Cu film is formed on the barrier metal film 15 by the sputtering method. Furthermore, a Cu film 16 is formed on the seed Cu film by an electrolytic plating method. Thereafter, annealing is performed. It is to be noted that the annealing may be performed after removing the Cu film 16 with a chemical solution.

Next, the Cu film 16 of the substrate outer peripheral portion is removed by the chemical solution. A removed width of the Cu film 16, that is, a length from the substrate edge 10 to the Cu film edge is set to 3 mm.

Thereafter, unnecessary portions of the Cu film. 16 and barrier metal film 15 formed on the first cap film 13 are removed using an orbital-type CMP apparatus in the same manner as in Ninth Embodiment. A Cu wiring layer connecting to the wiring layer 63a is formed as a first conductive layer to be through the above-described steps.

Next, a second diffusion barrier film 21 is formed, for example, in a film thickness of 30 nm to 200 nm on the first cap film 13 and Cu wiring by the CVD method. Next, immediately after a second low-k dielectric film 22 is formed, for example, in a film thickness of 100 nm to 1000 nm on the second diffusion barrier film 21 by the spin coating method. The second low-k dielectric film 22 of a substrate outer peripheral portion is removed by a chemical solution by a width B. The removed width B of the second low-k dielectric film 22 is set to, for example, 4 mm which is larger than the removed width A of the first low-k dielectric film 12 by 1 mm. Thereafter, the baking and curing are performed in the inactive gas atmosphere, and further the surface of the second low-k dielectric film 22 is reformed by irradiation with He plasma.

Next, as shown in FIG. 23B, a second cap film 23 is formed, for example, in a film thickness of 30 nm to 200 nm on the second low-k dielectric film 22 by the CVD method. Moreover, an,opening 24 is formed in the second cap film 23, second low-k dielectric film 22, and second diffusion barrier film 21 by the lithography technique and dry etching. Next, a barrier metal film 25 is formed on an inner wall of the opening 24 and the second cap film 23 by the sputtering method, and a seed Cu film is formed on the barrier metal film 25 by the sputtering method. Furthermore, a Cu film 26 is formed on the seed Cu film by the electrolytic plating method. Thereafter, the annealing is performed. Accordingly, the opening 24 is filled with a conductive film constituted of the barrier metal film 25, the seed Cu film, and the Cu film 26.

Next, the Cu film 26 of the substrate outer peripheral portion is removed by the chemical solution. A removed width of the Cu film 26 is set, for example, to 2 mm which is smaller than the removed width B of the second low-k dielectric film 22 by 2 mm. Thereafter, the CMP is performed on conditions similar to those of the Cu wiring layer of the first layer, and accordingly the unnecessary portions of the Cu film 26 and barrier metal film 25 formed on the second cap film 23 are removed. Accordingly, a via layer is formed as a second conductive layer.

Next, a third diffusion barrier film 31 is formed, for example, in a film thickness of 30 nm to 200 nm on the second cap film 23 and the via layer by the CVD method. Moreover, immediately after a third low-k dielectric film 32 is formed, for example, in a film thickness of 100 nm to 1000 nm on the third diffusion barrier film 31 by the spin coating method, the third low-k dielectric film 32 of a substrate outer peripheral portion is removed by a chemical solution by a width C. The removed width C of the third low-k dielectric film 32 is, for example, 5 mm which is larger than the removed width B of the second low-k dielectric film 22 by 1 mm. Thereafter, the baking and curing are performed in the inactive gas atmosphere, and further the surface of the third low-k dielectric film 32 is reformed by irradiation with He plasma.

Next, as shown in FIG. 23C, a third cap film 33 is formed, for example, in a film thickness of 30 nm to 200 nm on the third low-k dielectric film 32 by the CVD method. Moreover, an opening 34 is formed in the third cap film 33, third low-k dielectric film 32, and third diffusion barrier film 31 by the lithography technique and dry etching. Next, a barrier metal film 35 is formed on an inner wall of the opening 34 and the third cap film 33 by the sputtering method, and a seed Cu film is formed on the barrier metal film 35 by the sputtering method. Furthermore, a Cu film 36 is formed on the seed Cu film by the electrolytic plating method. Thereafter, the annealing is performed. Accordingly, the opening 34 is filled with a conductive film constituted of the barrier metal film 35, the seed Cu film, and the Cu film 36.

Next, the Cu film 36 of the substrate outer,peripheral portion is removed by the chemical solution. A removed width of the Cu film 36 is set, for example, to 2 mm which is smaller than the removed width C of the third low-k dielectric film 32 by 3 mm. Thereafter, the CMP is performed on conditions similar to those of the Cu wiring layer of the first conductive layer, and accordingly unnecessary portions of the Cu film 36 and barrier metal film 35 formed on the second cap film 33 are removed. Accordingly, a Cu wiring layer is formed as a third conductive layer.

As described above, in Fourteenth Embodiment, a difference between the edge removed width of the upper low-k dielectric film and that of the lower low-k dielectric film is set to 0.4 mm or more, and accordingly generation of the steep stepped portion of the low-k dielectric films in the substrate edge is avoided. Accordingly, a CMP pressure applied to the lower low-k dielectric film edge in the Cu-CMP of the upper can be largely reduced, and the lower low-k dielectric film in the Cu-CMP can be rapidly prevented from being peeled. When the edge removed width difference is increased to 0.7 mm or more, 1.0 mm or more, the stepped portion of the low-k dielectric film can further be eliminated. Even when a low-k dielectric film having a low Young's modulus or a low-k dielectric constant is used, the low-k dielectric film in the Cu-CMP can be prevented from being peeled.

Therefore, yield can be enhanced, and reliability of the semiconductor mounted device can be improved. A Cu damascene wiring using the low-k dielectric film is applicable to the wiring of the semiconductor device, and performance of the semiconductor mounted device can be enhanced.

Fifteenth Embodiment

In Fifteenth Embodiment of the present invention, the above-described multilayered wiring structure of Tenth Embodiment is applied to a wiring of a semiconductor mounted device. Concretely, the Tenth embodiment is applied to the wiring on the semiconductor chip, when packaging a semiconductor chip into a module.

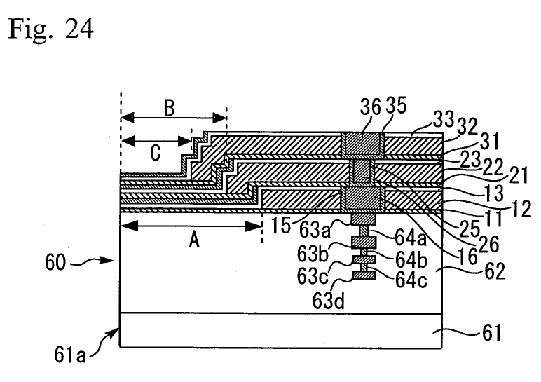

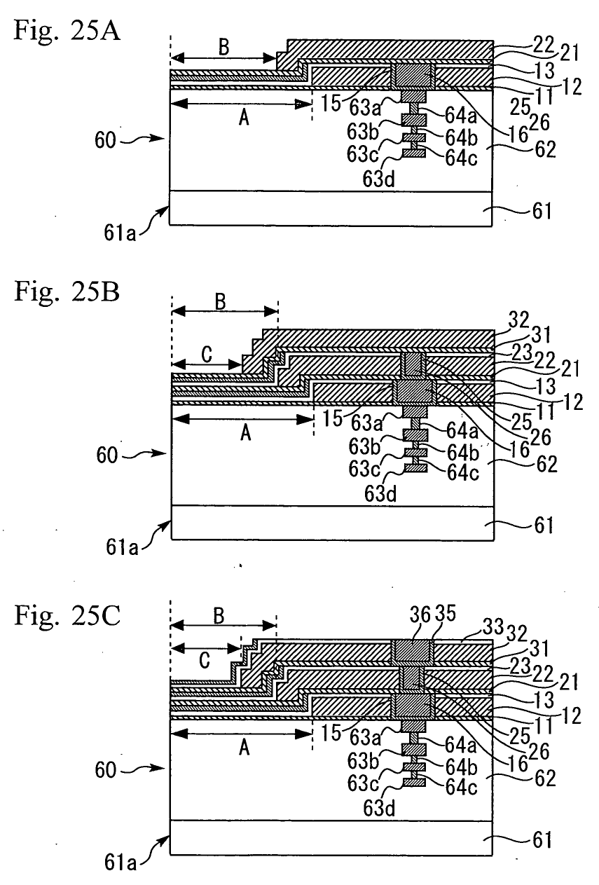

In Fourteenth Embodiment, the case where the edge removed width of the upper low-k dielectric film is set to be larger than that of the lower low-k dielectric film, that is, a case where the lower low-k dielectric film edge is on the side of a substrate outer periphery from the upper low-k dielectric film edge has been described. In Fifteenth Embodiment, a case where the edge removed width of the upper low-k dielectric film is set to be smaller than that of the lower low-k dielectric film, that is, a case where the upper low-k dielectric film edge is on the side of the substrate outer periphery from the lower low-k dielectric film edge will be described. Since other respects are similar to those of Fourteenth Embodiment, different respects from Fourteenth Embodiment will be mainly described with reference to FIGS. 24 and 25A to 25C. FIG. 24 is a sectional view showing a semiconductor mounted device according to Fifteenth Embodiment. FIGS. 25A to 25C are process sectional views showing a method of manufacturing a semiconductor mounted device according to Fifteenth Embodiment.

As shown in FIG. 24, a semiconductor chip 60 is formed on a substrate 61. The semiconductor chip 60 comprises a semiconductor element, and a multilayered wiring structure 62 having multilevel wiring layers 63a, 63b, 63c, 63d and via-contacts 64a, 64b, 64c which connect the layers to one another. A multilayered wiring structure of Tenth Embodiment is applied onto the semiconductor chip 60. Three layers of low-k dielectric films 12, 22, 32 are stacked on the semiconductor chip 60, and a conductive layer is formed in each low-k dielectric film.

As shown in FIG. 24, a first low-k dielectric film 12 in the vicinity of a substrate edge 10 is removed by a removed width A, a second low-k dielectric film 22 is removed by a removed width B which is smaller than the removed width A by 0.7 mm or more, and a third low-k dielectric film 32 is removed by a removed width C which is smaller than the removed width B by 0.7 mm or more. Accordingly, a second low-k dielectric film 22 edge is positioned on the substrate outer peripheral side from a first low-k dielectric film 12 edge, and further a third low-k dielectric film 32 edge is positioned on the substrate outer peripheral side from the second low-k dielectric film 22 edge. Therefore, the first low-k dielectric film 12 edge is coated with the second low-k dielectric film 22, and the second low-k dielectric film 22 edge is coated with the third low-k dielectric film 32. Other respects are similar to those of Fourteenth Embodiment.

Next, a method of manufacturing the semiconductor device will be described.

First, as shown in FIG. 25A, a semiconductor chip 60 is formed using the method similar to that of Fourteenth Embodiment.

Next, a first diffusion barrier film 11 is formed on the semiconductor chip 60, and is coated with a first low-k dielectric film 12. Immediately after the coating, the first low-k dielectric film 12 of a substrate outer peripheral portion is removed from a substrate edge 10 by a chemical solution by a width A. Thereafter, baking and curing are performed, and further the surface of the first low-k dielectric film 12 is reformed by He plasma.

Next, a first cap film 13 is formed on the first low-k dielectric film 12. Moreover, an opening 14 reaching the upper surface of the contact 8 is formed in the first cap film 13, first low-k dielectric film 12, and first diffusion barrier film 11. Thereafter, the opening 14 is filled with a barrier metal film 15 and a metal film 16 which are Cu films using a method similar to that of Thirteenth Embodiment, and accordingly a Cu wiring layer is formed as a first conductive layer.

Next, a second diffusion barrier film 21 is formed on the first cap film 13 and Cu wiring, and coated with a second low-k dielectric film 22. Immediately after the coating, the second low-k dielectric film 22 of a substrate outer peripheral portion is removed by a chemical solution by a width B which is smaller than the width A of the first low-k dielectric film 12 by 0.7 mm or more. Accordingly, a second low-k dielectric film 22 edge is positioned on the substrate outer peripheral side from the first low-k dielectric film 12 edge by 0.7 mm or more.

Next, as shown in FIG. 25B, a second cap film 23 is formed on the second low-k dielectric film 22. Moreover, a via hole which is an opening 24 is formed in the second cap film 23, second low-k dielectric film 22, and second diffusion barrier film 21. Thereafter, the opening 24 is filled with a barrier metal film 25 and a metal film 26 using a method similar to that of Twelfth Embodiment, and accordingly a via layer is formed as a second conductive layer.

Next, a third diffusion barrier film 31 is formed on the second cap film 23 and the via layer, and is coated with a third low-k dielectric film 32. Immediately after the coating, the third low-k dielectric film 32 of a substrate outer peripheral portion is removed by a chemical solution by a width C which is smaller than the removed width B of the second low-k dielectric film 22 by 0.7 mm or more. Accordingly, a third low-k dielectric film 32 edge is positioned on the substrate outer peripheral side from the second low-k dielectric film 22 edge by 0.7 mm or more and from the low-k dielectric film 12 edge by 1.4 mm or more.

Next, as shown in FIG. 25C, a third cap film 33 is formed on the third low-k dielectric film 32. Moreover, an opening 34 is formed in the third cap film 33, third low-k dielectric film 32, and third diffusion barrier film 31. Thereafter, the opening 34 is filled with a barrier metal film 35 and a metal film 36 which are Cu films using a method similar to that of Thirteenth Embodiment, and accordingly a Cu wiring layer is formed as a third conductive layer.

Also in Fifteenth Embodiment, in the same manner as in Thirteenth Embodiment, a difference between the edge removed width of the upper low-k dielectric film and that of the lower low-k dielectric film is set to 0.4 mm or more, and accordingly generation of the steep stepped portion of the low-k dielectric films in the substrate edge is avoided. Accordingly, a CMP pressure applied to the lower low-k dielectric film edge in the Cu-CMP of the upper can be largely reduced, and the lower low-k dielectric film in the Cu-CMP can be rapidly prevented from being peeled. When the edge removed width difference is increased to 1.0 mm or more, the stepped portion of the low-k dielectric film can further be eliminated. Even when a low-k dielectric film having a low Young's modulus or a low-k dielectric constant is used, the low-k dielectric film in the Cu-CMP can be prevented from being peeled.

Moreover, in Fifteenth Embodiment, the upper low-k dielectric film edge is positioned outside the lower low-k dielectric film edge at a time when the Cu film is removed with a chemical solution (immediately before the Cu-CMP). That is, the lower low-k dielectric film edge is coated with the upper low-k dielectric film in the Cu-CMP. Therefore, the lower low-k dielectric film can further be prevented from being peeled in the Cu-CMP by an anchor effect as compared with Fifth Embodiment.

Therefore, yield can be enhanced, and reliability of the semiconductor device can be improved. A Cu damascene wiring using the low-k dielectric film is applicable to the wiring of the semiconductor device, and performance of the semiconductor device can be enhanced.

Sixteenth Embodiment

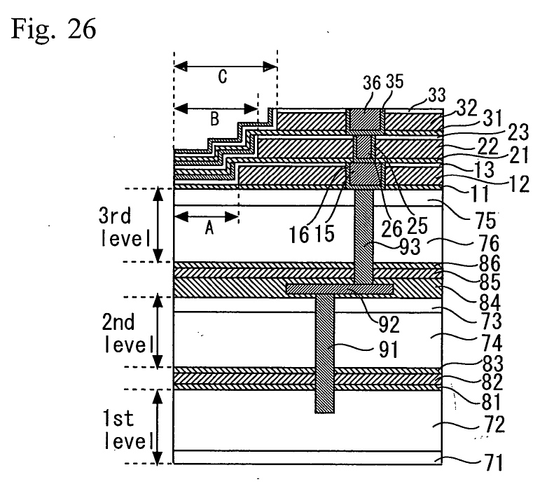

In Sixteenth Embodiment of the present invention, the above-described multilayered wiring structure of Ninth or Tenth Embodiment is applied to a wiring of a semiconductor mounted device comprising a multilayered substrate. FIG. 26 is a sectional view showing a semiconductor mounted device according to Sixteenth Embodiment.

As shown in FIG. 26, in the semiconductor mounted device, a first-level semiconductor chip (hereinafter referred to simply as the “chip”) having a substrate 71 and a multilayered wiring structure 72, a second-level chip having a substrate 73 and a multilayered wiring structure 74, and a third-level chip having a substrate 75 and a multilayered wiring structure 76 are stacked. Concretely, the first-level chip is face-to-face connected to the second-level chip using a low-k dielectric film 82 as an adhesive layer, and the second-level chip is face-to-face connected to the third-level chip using a low-k dielectric film 85 as an adhesive layer. Insulating layers 81, 83 and insulating layers 84, 86 functioning as diffusion barrier films are formed in lower and uppers of the low-k dielectric films 82, 85, respectively. A wiring layer 92 is formed in the insulating film 84. A bridge via-contact 91 connecting to the wiring layer 92 is formed in the first and second-level chips continuously. A bridge via-contact 93 connecting to the wiring layer 92 is formed in the third-level chip. Accordingly the chips stacked in the three levels are electrically connected to one another.

A multilayered wiring structure to be electrically connected to the bridge via-contact 93 is formed on the third-level chip.

Also in Sixteenth Embodiment, since a difference between the edge removed width of the upper low-k dielectric film and that of the lower low-k dielectric film is set to 0.4 mm or 0.7 mm or more in the same manner as in Fourteenth or Fifteenth Embodiments, any steep stepped portion of the low-k dielectric films is prevented from being disposed in a substrate edge. Accordingly, a CMP pressure applied to the lower low-k dielectric film edge in the Cu-CMP of the upper can be largely reduced, and the lower low-k dielectric film in the Cu-CMP can be rapidly prevented from being peeled. Moreover, when the edge removed width difference is increased to 0.7 mm or more, 1.0 mm or more, the stepped portion of the low-k dielectric film can further be eliminated. Even when a low-k dielectric film having a low Young's modulus or a low dielectric constant is used, the low-k dielectric film in the Cu-CMP can be prevented from being peeled.

Therefore, yield can be enhanced, and reliability of the semiconductor mounted device can be improved. A Cu damascene wiring using the low-k dielectric film is applicable to the wiring of the semiconductor device, and performance of the semiconductor mounted device can be enhanced.

This invention, when practiced illustratively in the manner described above, provides the following major effects:

According to the present invention, as described above, the removed width of the conductive film is set to be different from that of the low-k dielectric film by 1 mm or more, and accordingly the low-k dielectric film can be prevented from being peeled in polishing the conductive film.

Moreover, according to the present invention, when the substrate edge removed width of the low-k dielectric film of the upper is set to be smaller by 0.7 mm or more or larger by 0.4 mm or more than that of the low-k dielectric film of the lower, the low-k dielectric film can be prevented from being peeled in polishing the conductive film.

Further, the present invention is not limited to these embodiments, but variations and modifications may be made without departing from the scope of the present invention.

The entire disclosure of Japanese Patent Applications No. 2004-24540 and No. 2004-24539 filed on Jan. 30, 2004 containing specification, claims, drawings and summary are incorporated herein by reference in its entirety.

1. A method of forming a buried wiring in a low-k dielectric film, comprising:
forming a low-k dielectric film having a dielectric constant not exceeding 3 on an underlayer;
removing the low-k dielectric film by a first width from an edge of the underlayer;
forming a cap film on the low-k dielectric film, after removing the low-k dielectric film by the first width;
forming a groove in the cap film and the low-k dielectric film;
forming a conductive film in the groove and on the cap film;
removing the conductive film by a second width, different from the first width by at least 1 mm, from the edge of the underlayer; and
removing portions of the conductive film on the cap film, after removing the conductive film by the second width.

2. The method of forming a buried wiring according to claim 1, wherein the first width is in a range from 4 mm to 15 mm.

3. The method of forming a buried wiring according to claim 1, wherein the second width is smaller than the first width.

4. A method of manufacturing a semiconductor device, comprising:
forming a semiconductor element having a diffusion region in a substrate;
forming an interlayer insulating film covering the semiconductor element;
forming a contact connected to the diffusion region in the interlayer insulating film;
forming a low-k dielectric film having a dielectric constant not exceeding 3 on the contact and the interlayer insulating film;
removing the low-k dielectric film by a first width from an edge of the substrate;
forming a cap film on the low-k dielectric film, after removing the low-k dielectric film by the first width;
forming a groove reaching a top surface of the contact in the cap film and the low-k dielectric film;
forming a conductive film in the groove and on the cap film;
removing the conductive film by a second widths different from the first width by at least 1 mm, from the edge of the substrate; and
removing portions of the conductive film on the cap film, after removing the conductive film.

5. The method of manufacturing a semiconductor device according to claim 4, wherein the first width is in a range from 4 mm to 15 mm.

6. The method of manufacturing a semiconductor device according to claim 4, wherein the second width is smaller than the first width.

7. A method of manufacturing a semiconductor mounted device, comprising:
forming a low-k dielectric film having a dielectric constant not exceeding 3 on a semiconductor device having a semiconductor element;
removing the low-k dielectric film by a first width from an edge of the semiconductor device;
forming a cap film on the low-k dielectric film, after removing the low-k dielectric film by the first width;
forming a groove in the cap film and the low-k dielectric film;
forming a conductive film in the groove and on the cap film;
removing the conductive film by a second width, different from the first width by at least 1 mm, from the edge of the semiconductor device; and
removing portions of the conductive film on the cap film, after removing the conductive film by the second width.

8. A multilayered wiring structure comprising:
a first low-k dielectric film on a substrate and spaced by a first width from an edge of the substrate;
a first conductive layer in a first opening in the first low-k dielectric film;
a second low-k dielectric film on the first conductive film and the first low-k dielectric film, and spaced by a second widths smaller than the first width by at least 0.7 mm, from the edge of the substrate; and
a second conductive layer in a second opening in the second low-k dielectric film.

9. A multilayered wiring structure comprising:
a first low-k dielectric film on a substrate and spaced by a first width from an edge of the substrate;
a first conductive layer in a first opening in the first low-k dielectric film;
a second low-k dielectric film on the first conductive film and the first low-k dielectric film and spaced by a second widths larger than the first width by at least 0.4 mm, from the edge of the substrate; and
a second conductive layer in a second opening in the second low-k dielectric film.

10. A semiconductor device comprising:
a semiconductor element on a substrate and having a diffusion region;
an interlayer insulating film covering the semiconductor element;
a contact in the interlayer insulating film and connected to the diffusion region;
a first low-k dielectric film on the contact and the interlayer insulating film, and spaced by a first width from an edge of the substrate;
a first conductive layer in a first opening in the first low-k dielectric film;
a second low-k dielectric film on the first conductive layer and the first low-k dielectric film, and spaced by a second width, smaller than the first width by at least 0.7 mm, from the edge of the substrate; and
a second conductive layer in a second opening in the second low-k dielectric film.

11. A semiconductor device comprising:
a semiconductor element on a substrate and having a diffusion region;
an interlayer insulating film covering the semiconductor element;
a contact in the interlayer insulating film and connected to the diffusion region;
a first low-k dielectric film on the contact and the interlayer insulating film, and spaced by a first width from an edge of the substrate;
a first conductive layer in a first opening in the first low-k dielectric film;
a second low-k dielectric film on the first conductive layer and the first low-k dielectric film, and spaced by a second width, larger than the first width by at least 0.4 mm, from the edge of the substrate; and
a second conductive layer in a second opening in the second low-k dielectric film.

12. The semiconductor device according to claim 10, further comprising:
a third low-k dielectric film on the second low-k dielectric film and the second conductive layer, and spaced by the first width from the edge of the substrate;
a third conductive layer in a third opening in the third low-k dielectric film;
a fourth low-k dielectric film on the third low-k dielectric film and the conductive layer, and spaced by the second width from the edge of the substrate; and
a fourth conductive layer in a fourth opening in the fourth low-k dielectric film.

13. The semiconductor device according to claim 11, further comprising:
a third low-k dielectric film on the second low-k dielectric film and the second conductive layer, and spaced by the first width from the edge of the substrate;
a third conductive layer in a third opening in the third low-k dielectric film;
a fourth low-k dielectric film on the third low-k dielectric film and the conductive layer, and spaced by the second width from the edge of the substrate; and
a fourth conductive layer in a fourth opening in the fourth low-k dielectric film.

14. The semiconductor device according to claim 10, wherein the first width is different from the second width by at least 1.0 mm when the second low-k dielectric film has a Young's modulus of at least 4 GPa and a thickness of at least 600 nm.

15. The semiconductor device according to claim 11, wherein the first width is different from the second width by at least 1.0 mm when the second low-k dielectric film has a Young's modulus of at least 4 GPa and a thickness of at least 600 nm.

16. The semiconductor device according to claim 10, wherein the first width is different from the second width by at least 1.2 mm when the second low-k dielectric film has a Young's modulus of at least 2 GPa and less than 4 GPa and a thickness of at least 800 nm.

17. The semiconductor device according to claim 11, wherein the first width is different from the second width by at least 1.2 mm when the second low-k dielectric film has a Young's modulus of at least 2 GPa and less than 4 GPa and a thickness of at least 800 nm.

18. A semiconductor mounted device comprising:
a semiconductor chip having a semiconductor element and an upper wiring on a substrate;
a first low-k dielectric film on the semiconductor chip and spaced by a first width from an edge of the semiconductor chip;
a first conductive layer in a first opening in the first low-k dielectric film;
a second low-k dielectric film on the first conductive film and the first low-k dielectric film, and removed by a second width smaller than the first width by at least 0.7 mm from the edge of the substrate; and
a second conductive layer in a second opening in the second low-k dielectric film.

19. A semiconductor mounted device comprising:
a semiconductor chip having a semiconductor element and an upper wiring on a substrate;
a first low-k dielectric film on the semiconductor chip and spaced by a first width from an edge of the semiconductor chip;
a first conductive layer in a first opening in the first low-k dielectric film;
a second low-k dielectric film on the first conductive film and the first low-k dielectric film, and spaced by a second width, larger than the first width by at least 0.4 mm, from the edge of the substrate; and
a second conductive layer in a second opening in the second low-k dielectric film.
